(19) United States
(12) Patent Application Publication
(10) Pub. No.: US 2024/0355939 A1
(43) Pub. Date: Oct. 24, 2024

(54) Optical Sensor Device

(71) Applicant: Artilux, Inc., Menlo Park, CA (US)

(72) Inventors: Chih-Wei Chen, HSINCHU COUNTY (TW); Cheng-Te Yu, HSINCHU COUNTY (TW)

(21) Appl. No.: 18/592,054

(22) Filed: Feb. 29, 2024

Related U.S. Application Data
(60) Provisional application No. 63/497,744, filed on Apr. 24, 2023.
(60) Provisional application No. 63/506,833, filed on Jun. 8, 2023.
(60) Provisional application No. 63/507,859, filed on Jun. 13, 2023.

(51) Int. Cl. H01L 31/0216; H01L 31/0203; H01L 31/028; H01L 31/12

(52) U.S. Cl. CPC H01L 31/02164; H01L 31/0203; H01L 31/028; H01L 31/125

(57) ABSTRACT

An optical sensor device and related methods are presented. For example, an optical sensor device can include a substrate, a light-receiving element including a first absorption region, and disposed on and electrically connected to the substrate, and a first light-emitting element disposed on and electrically connected to the substrate. The optical sensor device can include an encapsulating structure disposed over the substrate, and encapsulating the light-emitting element and the light-receiving element. The optical sensor device can include a shielding structure disposed over the encapsulating structure, including a first opening located over the first light-emitting element, and a second opening located over the light-receiving element. The first absorption region can include a non-shielded portion exposed to an optical signal under the second opening of the shielding structure and a shielded portion shielded from the optical signal by the shielding structure.

### CROSS-REFERENCE TO RELATED APPLICATIONS

This application claims benefit of U.S. Provisional Patent Application Ser. No. 63/497,744, entitled “Optical Sensor Device” and filed on Apr. 24, 2023, U.S. Provisional Patent Application Ser. No. 63/506,833, entitled “Optical Sensor Device” and filed on Jun. 8, 2023, and U.S. Provisional Patent Application Ser. No. 63/507,859, entitled “Optical Sensor Device” and filed on Jun. 13, 2023, which are each incorporated by reference herein in its entirety.

### BACKGROUND

Optical sensors may be used to detect optical signals and convert the optical signals to electrical signals that may be further processed by another circuitry. Optical sensors may be used in consumer electronics products, image sensors, high-speed optical receiver, data communications, direct/indirect time-of-flight (TOF) ranging or imaging sensors, medical devices, and many other suitable applications.

### SUMMARY

Optical sensor devices are being used in many systems, such as smartphones, wearable electronics, robotics, and autonomous vehicles, etc. for proximity detection, 2D/3D imaging, object recognition, image enhancement, material recognition, color fusion, health monitoring, and other relevant applications. The optical sensor device can be operable for different wavelength ranges, including visible (e.g., wavelength range 380 nm to 780 nm, or a similar wavelength range as defined by a particular application) and non-visible light. The non-visible light includes near-infrared (NIR, e.g., wavelength range from 780 nm to 1000 nm, or a similar wavelength range as defined by a particular application) and short-wavelength infrared (SWIR, e.g., wavelength range from 1000 nm to 3000 nm, or a similar wavelength range as defined by a particular application) light.

The present disclosure discloses an optical sensor device, which has at least one light-emitting element, a light-receiving element, and a control element. At least one light-emitting element and the light-receiving element are disposed over the control element to form a stack structure, which is beneficial to reducing the package size of the optical sensor device. The present disclosure also discloses an optical sensor device, which has a shielding structure above the light-emitting element and the light-receiving element. The shielding structure includes a plurality of openings corresponding to the light-emitting element and the light-receiving element.

An example aspect of the present disclosure is directed to an optical sensor device. The optical sensor device includes a substrate and a light-receiving element including a first absorption region, and disposed on and electrically connected to the substrate. The optical sensor device includes a first light-emitting element disposed on and electrically connected to the substrate. The optical sensor device includes an encapsulating structure disposed over the substrate, and encapsulating the light-emitting element and the light-receiving element and a shielding structure disposed over the encapsulating structure, including a first opening located over the first light-emitting element, and a second opening located over the light-receiving element. The first absorption region includes a non-shielded portion exposed to an optical signal under the second opening of the shielding structure and a shielded portion shielded from the optical signal by the shielding structure.

In some implementations, the shielding structure directly contacts the encapsulating structure.

In some implementations, the optical sensor device further includes a second light-emitting element disposed on and electrically connected to the substrate, wherein the first light-emitting element and the second light-emitting element are exposed under the first opening of the shielding structure.

In some implementations, the shielding structure includes a third opening separated from the second opening and located over the light-receiving element.

In some implementations, a dimension of the second opening is different from that of the third opening.

In some implementations, a distance between the first opening and the third opening is larger than a distance between the first opening and the second opening, and an area of the third opening is larger than that of the second opening.

In some implementations, an area ratio of the third opening to the second opening is in a range between 1.2 to 2.

In some implementations, the light-receiving element includes a second absorption region separated from the first absorption region, the second absorption region includes a shielded portion shielded by the shielding structure and a non-shielded portion is exposed under the third opening.

In some implementations, the first light-emitting element is closer to the first absorption region than to the second absorption region, and an area of the shielded portion of the second absorption region is smaller than that of the shielded portion of the first absorption region.

In some implementations, a distance between the first light-emitting element and the second absorption region is greater than a distance between the first light-emitting element and the first absorption region, and an area of the non-shielded portion of the second absorption region is greater than that of the non-shielded portion of the first absorption region.

In some implementations, the shielding structure includes a covering portion and a separation portion extending from the covering portion toward the substrate.

In some implementations, the separation portion is located between the light-emitting element and the light-receiving element.

In some implementations, the separation portion is distant from the substrate and the encapsulating structure is filled between the separation portion and the substrate.

In some implementations, the separation portion has a stepped shape which includes a narrower part and a wider part, and the narrower part is closer to the substrate than the wider part.

In some implementations, a topmost surface of the encapsulating structure is coplanar with that of the shielding structure.

In some implementations, a topmost surface of the encapsulating structure has an elevation lower than that of the shielding structure.

In some implementations, the light-receiving element includes a second absorption region separated from the first absorption region and is exposed from the shielding structure.

In some implementations, a topmost surface of the encapsulating structure has a plurality of scratches.

In some implementations, the encapsulating structure includes a material transparent to a NIR light or a SWIR light.

In some implementations, the light-receiving element includes a photoelectronic device having a detecting region including germanium.

Another example aspect of the present disclosure is directed to an optical sensor device. The optical sensor device includes a control element including a first conductive pad and a second conductive pad. The optical sensor device includes an optoelectronic element having a first electrical contact and a second electrical contact, wherein the optoelectronic element is disposed over the first conductive pad. The optical sensor device includes a conductive ball disposed over the second conductive pad and a conductive paste in contact with the optoelectronic element and the conductive ball. The first electrical contact of the optoelectronic element and the control element are electrically coupled at least via the conductive ball and the conductive paste.

In some implementations, the conductive paste covers a portion of a side of the optoelectronic element.

In some implementations, the first electrical contact of the optoelectronic element and the control element are electrically coupled via the first conductive pad of the control element.

In some implementations, a distance between the first electrical contact and the first conductive pad is less than a height of the conductive ball.

In some implementations, the second electrical contact is located on an opposite side to the first electrical contact.

In some implementations, the second electrical contact is electrically coupled to the control element via a bonded wire.

In some implementations, a material of the conductive ball is different from that of the first conductive pad and the second conductive pad.

In some implementations, a material of the conductive ball is different from that of the conductive paste.

In some implementations, the control element further includes a dielectric layer filled in an aisle between each conductive pad.

In some implementations, the dielectric layer has an elevation higher than that of the first conductive pad.

In some implementations, the optical sensor device further includes a substrate, the control element disposed over the substrate.

In some implementations, the optical sensor device further includes a lid disposed on the substrate and including an opening located over the optoelectronic element.

In some implementation, the lid is adhered to the control element and the substrate to form a cavity for accommodating the optoelectronic element.

In some implementations, the optical sensor device further includes a transmissive plate adhered to the lid and covering the optoelectronic element.

In some implementations, the optical sensor device further includes an encapsulation material filled between the lid and the optoelectronic element to form an encapsulating layer.

In some implementations, the encapsulating layer has an upper surface over the optoelectronic element and having a concave shape.

In some implementations, the encapsulating layer has an upper surface over the optoelectronic element and having a convex shape.

Another example aspect of the present disclosure is directed to a method for packaging an optical sensor device including a control element that includes a first conductive pad and a second conductive pad. The method includes placing a conductive ball on the second conductive pad. The method includes placing a conductive paste to cover the conductive ball, the first conductive pad, and the second conductive pad. The methods includes placing an optoelectronic element aligned with the first conductive pad and in contact with the conductive paste.

In some implementations, the method includes placing the control element on a substrate.

In some implementations, the method includes: adhering a lid to the substrate, wherein the lid includes an opening; and filling an encapsulating material from the opening to encapsulate the control element and the optoelectronic element.

Another example aspect of the present disclosure is directed to an optical sensor device. The optical sensor device includes a substrate, a first optoelectronic element disposed on the substrate, and a second optoelectronic element disposed on the substrate. The optical sensor device includes a lid coupled to the substrate and configured to form a first cavity to accommodate the first optoelectronic element and a second optoelectronic element to accommodate the second optoelectronic element. The lid includes: a first opening located above the first optoelectronic element; a second opening located above the second optoelectronic element; a dam surrounding the first optoelectronic element and the second optoelectronic element; a partition wall coupled to the dam and configured to light isolate the first optoelectronic element and the second optoelectronic element; and a first vent coupled to the first opening and the first cavity to stabilize an air pressure of the first cavity. The optical sensor device includes a first transmissive plate located between the lid and the first optoelectronic element and connected to the lid. The first transmissive plate covers the first opening and a portion of the first vent.

In some implementations, the first transmissive plate is distant from the partition wall by a non-zero distance.

In some implementations, the first transmissive plate is adhered to the lid through an adhesive material.

In some implementations, the lid includes a stopper located at the peripheral area of the first opening to prevent the adhesive material from flowing into the first opening.

In some implementations, the lid includes a blocker located on a side of the vent and coupled to the partition wall, the blocker has a thickness larger than that of the stopper.

In some implementations, the first transmissive plate is in contact with the blocker.

In some implementations, the partition wall has a thickness less than that of the dam.

In some implementations, the lid includes a first covering portion connected to the dam and surrounds the first opening and a second covering portion connected to the first covering portion to cover the first vent, the second covering portion has a thickness less than that of the first covering portion.

### BRIEF DESCRIPTION OF THE DRAWINGS

The foregoing aspects and many of the advantages of this application will become more readily appreciated as the same becomes better understood by reference to the following detailed description, when taken in conjunction with the accompanying drawings:

FIG. 1A shows a top view of an optical sensor device in accordance with one embodiment of the present disclosure.

FIG. 1B shows a cross-sectional view of an optical sensor device in accordance with one embodiment of the present disclosure.

FIG. 2 shows a top view of an optical sensor device without the lid and the transmissive plate in accordance with one embodiment of the present disclosure.

FIG. 3 shows a cross-sectional view taken along the line BB′ in FIG. 2.

FIG. 4 shows a bonding process flow of an optoelectronic element in accordance with one embodiment of the present disclosure.

FIGS. 5A˜5D show several cross-sectional views of optical sensor devices in accordance with different embodiments of the present disclosure.

FIG. 6 shows an encapsulating process flow of an optical sensor device in accordance with one embodiment of the present disclosure.

FIG. 7A shows a perspective view of a lid from the bottom side in accordance with one embodiments of the present disclosure.

FIG. 7B shows a cross-sectional view taken along the line BB′ of the lid shown in FIG. 7A and assembled to form an optical sensor device.

FIG. 7C shows a cross-sectional view taken along the line CC′ of the lid shown in FIG. 7A and assembled to form an optical sensor device.

FIG. 8A shows a top view of an optical sensor device in accordance with another embodiment of the present disclosure.

FIG. 8B shows a cross-sectional view of an optical sensor device in accordance with another embodiment of the present disclosure.

FIG. 8C shows a schematic diagram illustrating the separation of the shielding structure and the circuit of an optical sensor device in accordance with another embodiment of the present disclosure.

FIG. 9 shows a schematic diagram illustrating the crosstalk signal of a sensing module in accordance with one embodiment of the present disclosure.

FIG. 10A shows a cross-sectional view of an optical sensor device in accordance with another embodiment of the present disclosure.

FIG. 10B shows a cross-sectional view of an optical sensor device in accordance with another embodiment of the present disclosure.

FIG. 10C shows a cross-sectional view of an optical sensor device in accordance with another embodiment of the present disclosure.

FIG. 10D shows a cross-sectional view of an optical sensor device in accordance with another embodiment of the present disclosure.

FIG. 10E shows a cross-sectional view of an optical sensor device in accordance with another embodiment of the present disclosure.

FIG. 10F shows a cross-sectional view of an optical sensor device in accordance with another embodiment of the present disclosure.

FIG. 11A shows a top view of an optical sensor device in accordance with another embodiment of the present disclosure.

FIG. 11B shows a cross-sectional view of an optical sensor device in accordance with another embodiment of the present disclosure.

FIG. 11C shows a schematic diagram illustrating the separation of the shielding structure and the circuit of an optical sensor device in accordance with another embodiment of the present disclosure.

FIG. 12A shows a top view of an optical sensor device in accordance with another embodiment of the present disclosure.

FIG. 12B shows a cross-sectional view of an optical sensor device in accordance with another embodiment of the present disclosure.

FIG. 12C shows a schematic diagram illustrating the separation of the shielding structure and the circuit of an optical sensor device in accordance with another embodiment of the present disclosure.

FIG. 12D shows a circuit of an optical sensor device in accordance with another embodiment of the present disclosure.

FIG. 13A shows a cross-sectional view of an optical sensor device in accordance with another embodiment of the present disclosure.

FIG. 13B shows a cross-sectional view of an optical sensor device in accordance with another embodiment of the present disclosure.

FIG. 13C shows a cross-sectional view of an optical sensor device in accordance with another embodiment of the present disclosure.

FIG. 13D shows a cross-sectional view of an optical sensor device in accordance with another embodiment of the present disclosure.

FIG. 14A shows an earbud including an optical sensor device in accordance with one embodiments of the present disclosure.

FIG. 14B shows a pair of glasses including an optical sensor device in accordance with one embodiments of the present disclosure.

FIG. 15 shows a light-receiving element in accordance with one embodiments of the present disclosure.

FIG. 16 shows an optical sensor module in accordance with one embodiments of the present disclosure.

### DETAILED DESCRIPTION

The following embodiments accompany the drawings to illustrate the concept of the present disclosure. In the drawings or descriptions, similar or identical parts use the same reference numerals, and in the drawings, the shape, thickness, or height of the element can be reasonably expanded or reduced. The embodiments listed in the present application are only used to illustrate the present application and are not used to limit the scope of the present application. Any obvious modification or change made to the present application does not depart from the spirit and scope of the present application.

In general, an optical sensor device can be used to measure various bioinformation from a user. For example, a photoplethysmogram (PPG) is an optically obtained plethysmogram, which can be used to determine various bioinformation such as heart rate, calories, skin moisture, SpO₂, blood pressure, etc. In some cases, a user may be wearing multiple wearable devices each having one or more optical sensor devices that are capable of measuring bioinformation. For example, a user may be wearing a pair of earbuds, where each earbud includes an optical sensor device that can measure bioinformation of the user.

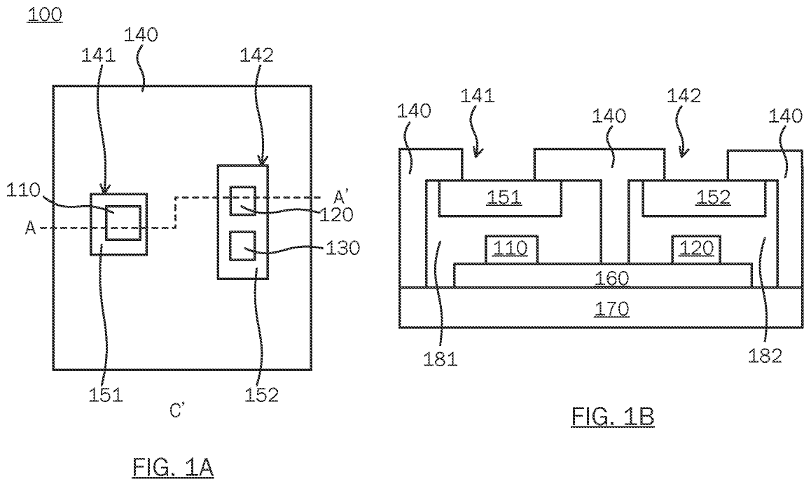

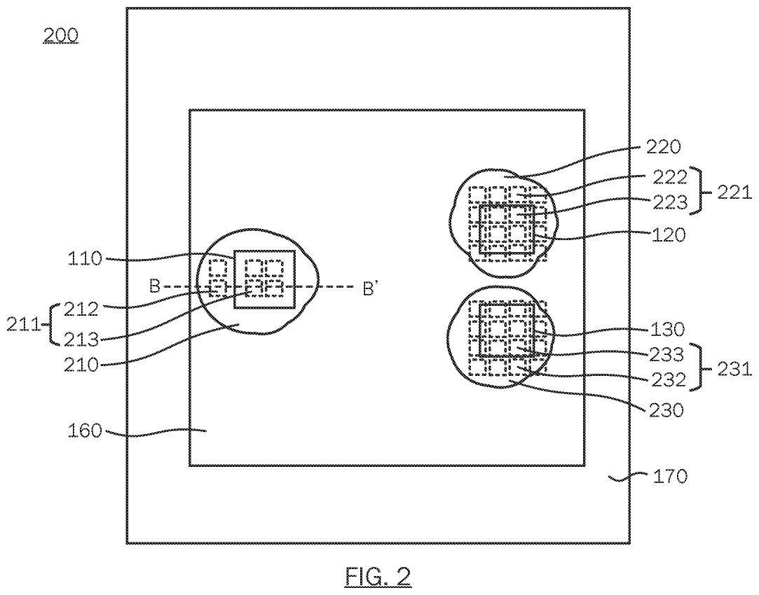

FIG. 1A shows a top view of an optical sensor device 100 in accordance with one embodiment of the present disclosure. FIG. 1B shows a cross-sectional view taken along the line AA′ in FIG. 1A. As shown in FIGS. 1A˜1B, the optical sensor device 100 includes a plurality of optoelectronic elements 110, 120, 130, a control element 160, a substrate 170, a lid 140, a first transmissive plate 151, and a second transmissive plate 152. The plurality of optoelectronic elements can include a light-receiving element 110, a first light-emitting element 120, and a second light-emitting element 130 disposed over and electrically connected to the control element 160 to form a stack structure. The control element 160 is disposed over and electrically connected to the substrate 170. The light-receiving element 110, the first light-emitting element 120, and the second light-emitting element 130 are stacked on the control element 160 and the substrate 170 to reduce the package size of the optical sensor device 100. The lid 140 is disposed over the substrate 170 to protect the light-receiving element 110, the first light-emitting element 120, the second light-emitting element 130, and the control element 160 and block the unwanted light entering the light-receiving element 110. The lid 140 has a first opening 141 located over the light-receiving element 110 for receiving the reflected light from the object (not shown), and a second opening 142 located over the first light-emitting element 120 and the second light-emitting element 130 for transmitting the light emitted from the light-emitting elements 120 and 130 towards the object (not shown). In the top view, the light-receiving element 110 is exposed to the lid 140 through the first opening 141, and the first light-emitting element 120 and the second light-emitting element 130 are exposed to the lid 140 through the second opening 142.

The lid 140 is adhered to the control element 160 and the substrate 170 through an adhesion material to form a first cavity 181 and a second cavity 182. The first cavity 181 is used to accommodate the light-receiving element 110, and the second cavity 182 is used to accommodate the first light-emitting element 120 and the second light-emitting element 130. The first cavity 181 and the second cavity 182 are separated and light isolated by the lid 140. In some embodiments, the cavities 181 and 182 can be filled with air. In some other embodiments, the cavities 181 and 182 can be filled with encapsulation materials, such as silicone-based resin or epoxy-based resin. The first transmissive plate 151 is adhered to the lid 140 and covers the first opening 141 to be configured as a protective transmissive cover and/or a filter for the light-receiving element 110. The second transmissive plate 152 is adhered to the lid 140 and covers the second opening 142 to be configured as a protective transmissive cover and/or a filter for the first light-emitting element 120 and the second light-emitting element 130. In some implementations, the first transmissive plate 151 and the second transmissive plate 152 are configured to pass through light in a wavelength range corresponding to the emission wavelength of the light-emitting elements 120 and 130 and the reception wavelength of the light-receiving element 110. The width of the first transmissive plate 151 is larger than that of the first opening 141 and the first transmissive plate 151 is adhered to the lid 140 from the bottom side. The width of the second transmissive plate 152 is larger than that of the second opening 142 and the second transmissive plate 152 is adhered to the lid 140 from the bottom side. The elevation of the topmost surface of the first transmissive plate 151 or the second transmissive plate 152 is lower than that of the topmost surface of the lid 140. Such arrangement reduces an overall height of the optical sensor device 100. In another embodiment, the first transmissive plate 151 and the second transmissive plate 152 are adhered to the lid 140 from the top side, and the elevation of the topmost surface of the first transmissive plate 151 or the second transmissive plate 152 is higher than that of the topmost surface of the lid 140. Such arrangement reduces the complexity for assembling the optical sensor device 100, where for example the first transmissive plate 151 and the second transmissive plate 152 can be formed as a single transmissive plate.

The light-receiving element 110 can include a single photoelectronic device or a plurality of photoelectronic devices arranged in an array. In an embodiment, the light-receiving element 110 includes a plurality of photoelectronic devices arranged in a one-dimensional array or a two-dimensional array. The photoelectronic device can include a supporting substrate and a detecting region supported by the supporting substrate. The detecting region can include Group-IV materials or Group-III-V materials and is configured to absorb photons. The Group-IV materials can include silicon (Si) or germanium (Ge). The supporting substrate can include a material, such as silicon, different from that of the detecting region (e.g., Ge). The light-receiving element 110 can detect visible light, or non-visible light according to the application. The visible light can include blue, navy, green, yellow, or red light. The non-visible light can include NIR or SWIR.

The first light-emitting element 120 and the second light-emitting element 130 can be semiconductor light-emitting elements, such as a light-emitting diode (LED), a laser diode, a vertical-cavity surface-emitting laser (VCSEL), or organic light-emitting diode (OLED). The light-emitting elements 120 and 130 can emit light corresponding to the detecting wavelength of the light-receiving element 110.

The control element 160 can be configured to control the light-emitting elements 120, 130 and the light-receiving element 110. The control element 160 can further be configured to process the signal received by the light-receiving element 110 to determine outputs such as bioinformation of a detected object (e.g., user). The control element 160 can be implemented by digital processor (DSP), general purpose processor, application-specific integrated circuit (ASIC), digital circuitry, software, or any combinations thereof.

The lid 140 can be a silicone-based resin, or epoxy-based resin and contain a light-absorbing substance that blocks unwanted light.

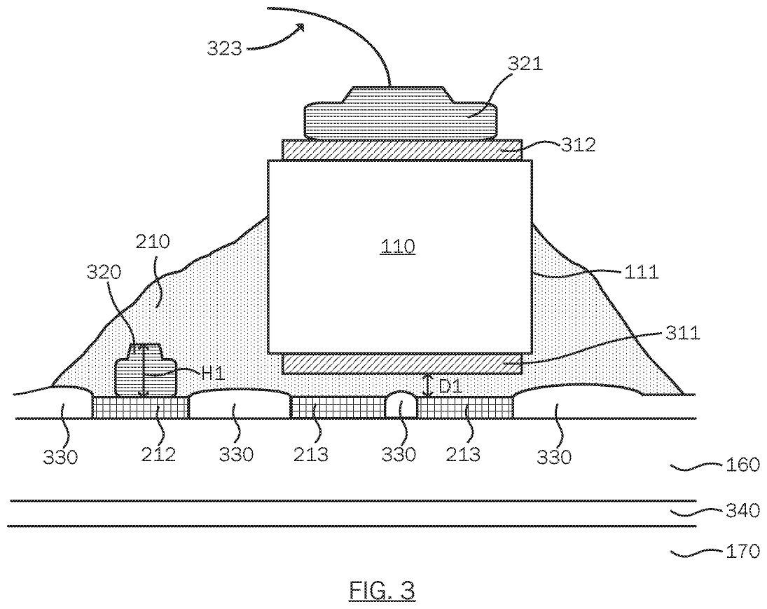

FIG. 2 shows a top view of an optical sensor device in accordance with one embodiment of the present disclosure. The optical sensor device 200 is similar to the optical sensor device 100, where the lid 140 and the transmissive plates 151 and 152 are absent. The control element 160 includes a first plurality of conductive pads 211 facing the light receiving element 110 and used to control the light-receiving element 110, a second plurality of conductive pads 221 facing the first light-emitting element 120 and used to control the first light-emitting element 120, and a third plurality of conductive pads 231 facing the second light-emitting element 130 and used to control the second light-emitting element 130. The first plurality of conductive pads 211 include a plurality of uncovered conductive pads 212 which are not covered by the light-receiving element 110 and a plurality of the covered conductive pads 213 which are covered by the light-receiving element 110. The first plurality of conductive pads 211 are electrically connected to the light-receiving element 110 through the first conductive paste 210. The second plurality of conductive pads 221 include a plurality of uncovered conductive pads 222 which are not covered by the first light-emitting element 120 and a plurality of the covered conductive pads 223 which are covered by the first light-emitting element 120. The second plurality of conductive pads 221 are electrically connected to the first light-emitting element 120 through the second conductive paste 220. The third plurality of conductive pads 231 include a plurality of uncovered conductive pads 232 which are not covered by the second light-emitting element 130 and a plurality of the covered conductive pads 233 which are covered by the second light-emitting element 130. The third plurality of conductive pads 231 are electrically connected to the second light-emitting element 130 through the third conductive paste 230. The plurality of the covered conductive pads 213 of the first plurality of conductive pads 211 are fully covered by the light-receiving element 110. The plurality of the covered conductive pads 223 of the second plurality of conductive pads 221 have a portion fully covered by the first light-emitting element 120 and another portion partially covered by the first light-emitting element 120. The plurality of the covered conductive pads 233 of the third plurality of conductive pads 231 have a portion fully covered by the second light-emitting element 130 and another portion partially covered by the second light-emitting element 130.

In another embodiment, in order to reduce the contact resistance between the conductive pads of the control element and the conductive paste, at least one conductive ball can be disposed on the conductive pads. The conductivity between the conductive ball and the conductive pad is better than that between the conductive glue and the conductive pad. FIG. 3 shows a cross-sectional view taken along the line BB′ in FIG. 2. The control element 160 is adhered to the substrate 170 through an adhesive layer 340. The adhesive layer 340 can be in the form of a paste or a film. The control element 160 includes a plurality of covered conductive pads 213 which are covered by the light-receiving element 110 and a plurality of uncovered conductive pads 212 which are not covered by the light-receiving element 110. A dielectric layer 330 is filled in the aisle between each covered conductive pad 213 and each uncovered conductive pad 212 to increase the flatness of the control element 160 and the electrical insulation between the conductive pads 212, 213. The dielectric layer 330 can include oxide or other isolation materials. The elevation of the dielectric layer 330 is slightly higher than that of the covered conductive pad 213 and the uncovered conductive pad 212. In another embodiment, the elevation of the dielectric layer 330 can be substantially equal to or slightly lower than that of the covered conductive pad 213 and the uncovered conductive pad 212. The light-receiving element 110 includes a first electrical contact 311 facing the control element 160 and a second electrical contact 312 located on the opposite side to the first electrical contact 311. A first conductive ball 320 is disposed over and electrically connected to at least one of the uncovered conductive pads 212. The first conductive paste 210 covers the first conductive ball 320, the plurality of the uncovered conductive pads 212, and the plurality of the covered conductive pads 213 to be electrically connected to the light-receiving element 110 and the control element 160. As shown in FIG. 3, the first conductive ball 320 is fully covered by the first conductive paste 210. In another embodiment, the first conductive ball 320 is partially covered by the first conductive paste 210, and the first conductive ball 320 has a portion exposed out the first conductive paste 210. In addition, the first conductive paste 210 covers a portion of a side 111 of the light-receiving element 110. A second conductive ball 321 is disposed over and electrically connected to the second electrical contact 312. The second electrical contact 312 is electrically connected to the control element 160 through a wire 323 to control the light-receiving element 110.

The distance D1 between the first electrical contact 311 and the covered conductive pad 213 is less than the height H1 of the first conductive ball 320. The material of the first conductive ball 320 is different from that of the covered conductive pad 213 and the uncovered conductive pad 212. The material of the first conductive ball 320 is different from that of the first conductive paste 210. The conductivity between the first conductive paste 210 and the first conductive ball 320 is better than that between the first conductive paste 210 and the covered conductive pad 213. The conductivity of the electrical connection between the light-receiving element 110 and the control element 160 can be increased by arranging the first conductive ball 320. In addition, there is no conductive ball between the light-receiving element 110 and the control element 160, so the flatness and precision of the bonding process of the light-receiving element 110 can be improved, which is beneficial for the light-receiving element receiving light.

The material of the first conductive ball 320 and the second conductive ball 321 can be metal, such as gold (Au), silver (Ag), copper (Cu), aluminum (Al), platinum (Pt), nickel (Ni), titanium (Ti), tin (Sn), or the alloys thereof, or the laminate combinations thereof. The material of the first electrical contact 311 and the second electrical contact 312 can be metal, such as gold (Au), silver (Ag), copper (Cu), aluminum (Al), platinum (Pt), nickel (Ni), titanium (Ti), tin (Sn), or the alloys thereof, or the laminate combinations thereof. The material of the uncovered conductive pad 212 and the covered conductive pad 213 can be metal, such as gold (Au), silver (Ag), copper (Cu), aluminum (Al), platinum (Pt), nickel (Ni), titanium (Ti), tin (Sn), or the alloys thereof, or the laminate combinations thereof. The first conductive paste 210 and the adhesive layer 340 can be a silicone-based resin, or epoxy-based resin and contain metal, such as aluminum, silver, copper, or another highly thermal conductive metal.

Referring back to FIG. 2, the second plurality of conductive pads 221 used to electrically connect to and control the first light-emitting element 120 includes a plurality of uncovered conductive pads 212. Similar to the connection structure of the light-receiving element 110, at least one conductive ball is disposed over and electrically connected to at least one of the uncovered conductive pads 222. The second conductive paste 220 covers the conductive ball on the uncovered conductive pad 222, the plurality of the uncovered conductive pads 222, and the plurality of the covered conductive pads 223 to be electrically connected to the first light-emitting element 120 and the control element 160. The third plurality of conductive pads 231 used to electrically connect to and control the second light-emitting element 130 includes a plurality of uncovered conductive pads 232. Similar to the connection structure of the light-receiving element 110, at least one conductive ball is disposed over and electrically connected to at least one of the uncovered conductive pads 232. The third conductive paste 230 covers the conductive ball on the uncovered conductive pad 232, the plurality of the uncovered conductive pads 232, and the plurality of the covered conductive pads 233 to be electrically connected to the second light-emitting element 130 and the control element 160. The connection structures between the light-emitting elements 120, 130 and the control element 160 are similar to the connection structure between the light-receiving element 110 and the control element 160, and can refer to the aforementioned descriptions.

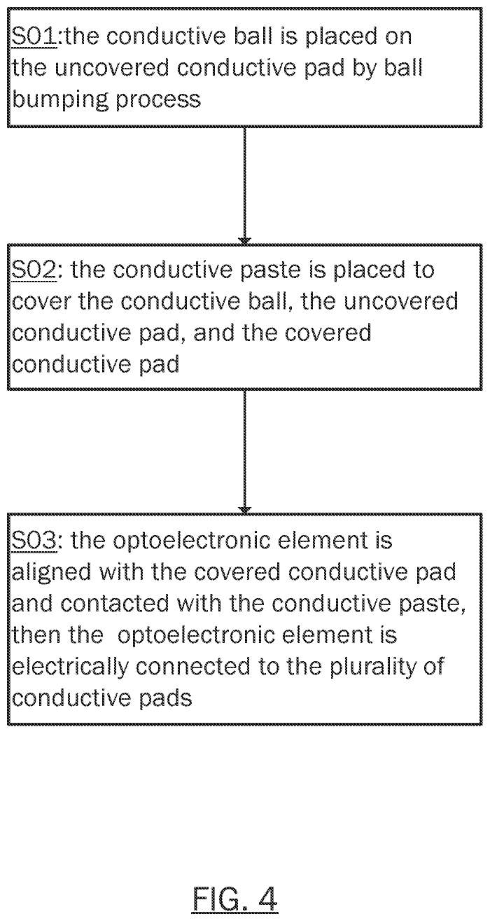

FIG. 4 shows a bonding process flow of an optoelectronic element in accordance with one embodiment of the present disclosure. As shown in step S01, the conductive ball is placed on the uncovered conductive pad of the plurality of conductive pads by the ball bumping process. Then, as shown in step S02, the conductive paste is placed to cover the conductive ball, and the uncovered conductive pad and the covered conductive pad of the plurality of conductive pads by printing, injection, dispensing, or the like. Subsequently, as shown in step S03, the optoelectronic element is aligned with the covered conductive pad and contacted with the conductive paste, then the optoelectronic element is electrically connected to the plurality of conductive pads.

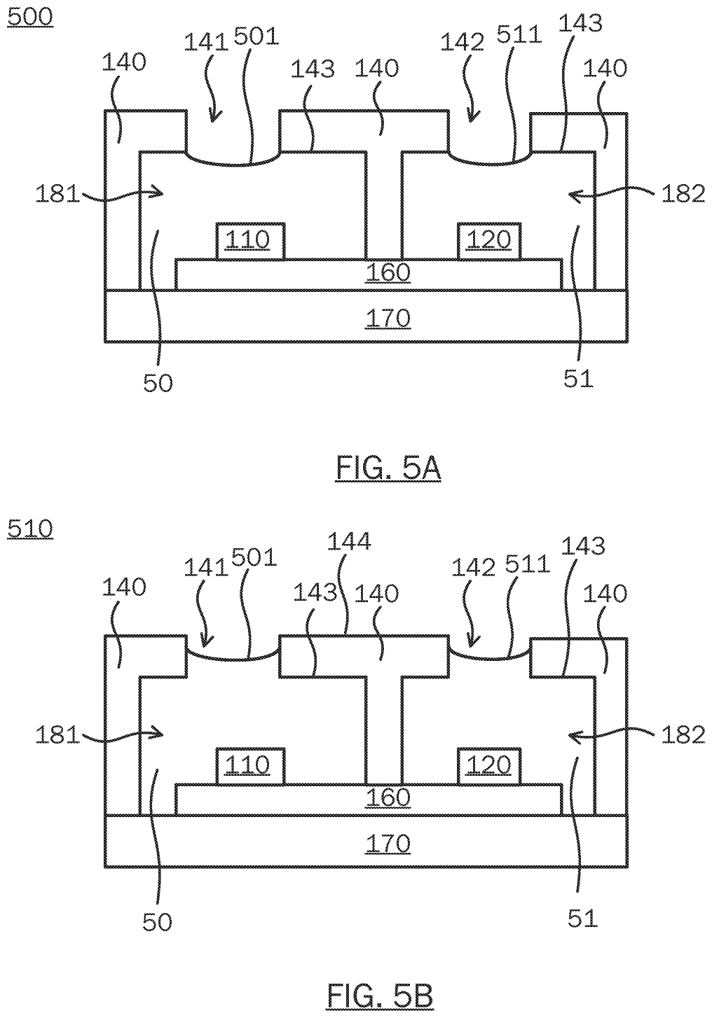

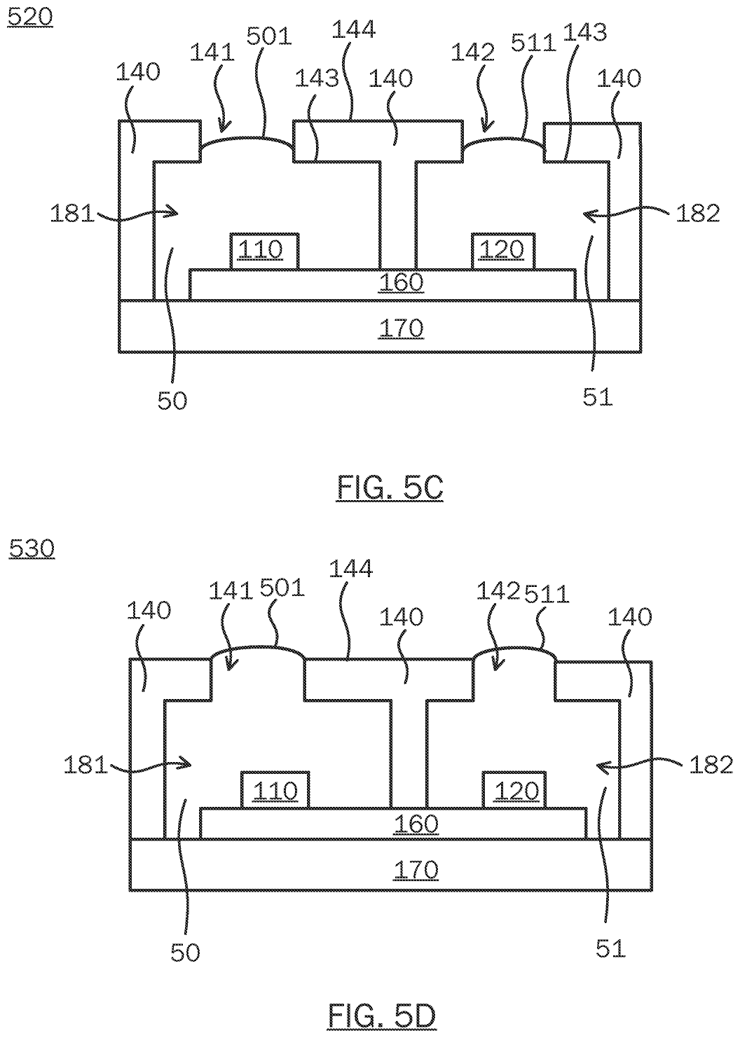

In another embodiment, the cavities 181 and 182 are filled with encapsulation materials. FIGS. 5A˜5D show several cross-sectional views of optical sensor devices in accordance with different embodiments of the present disclosure. Referring to FIG. 5A, the optical sensor device 500 includes a plurality of optoelectronic elements 110, 120, a control element 160, a substrate 170, a lid 140, a first encapsulating structure 50, and a second encapsulating structure 51. The plurality of optoelectronic elements can include a light-receiving element 110, a first light-emitting element 120 disposed over and electrically connected to the control element 160. The control element 160 is disposed over and electrically connected to the substrate 170. The lid 140 is adhered to the substrate 170 and the control element 160 to protect the light-receiving element 110 and the first light-emitting element 120 and form a first cavity 181 and a second cavity 182. The lid 140 has a first opening 141 located over the light-receiving element 110, and a second opening 142 located over the first light-emitting element 120. The first encapsulating structure 50 fills the first cavity 181 to encapsulate the light-receiving element 110. The second encapsulating structure 51 fills the second cavity 182 to encapsulate the first light-emitting element 120.

As shown in FIG. 5A, the first encapsulating structure 50 has an upper surface 501 over the light-receiving element 110, located in the first opening 141, and having a concave shape. The upper surface 501 has an elevation lower than the upper inner surface 143 of the lid 140. The upper surface 511 has the same structure as the upper surface 501. In another embodiment, as shown in FIG. 5B, the upper surface 501 or the upper surface 511 is located between the upper inner surface 143 and the upper surface 144 of the lid 140 and has a concave surface. In another embodiment, as shown in FIG. 5C, the upper surface 501 is over the light-receiving element 110, located between the upper inner surface 143 and the upper surface 144 of the lid 140, and has a convex shape. The upper surface 511 has the same structure as the upper surface 501. In another embodiment, as shown in FIG. 5D, the upper surface 501 or the upper surface 511 has an elevation higher than the upper surface 144 of the lid 140 and has a convex shape. In some implementations, a convex or a concave surface shape may be designed to manipulate (e.g., focus or defocus) light entering or leaving the optical sensor device. Such surface shape may be controlled by properties such as the dimensions of the opening 141/142, or any other controlling mechanisms.

The encapsulating structures 50, 51 can be a silicone-based resin or epoxy-based resin and transparent to the light transmitted from the light-emitting elements 120, 130, and the light detected by the light-receiving element 110. In one embodiment, the encapsulating structure is transparent to a NIR light or a SWIR light.

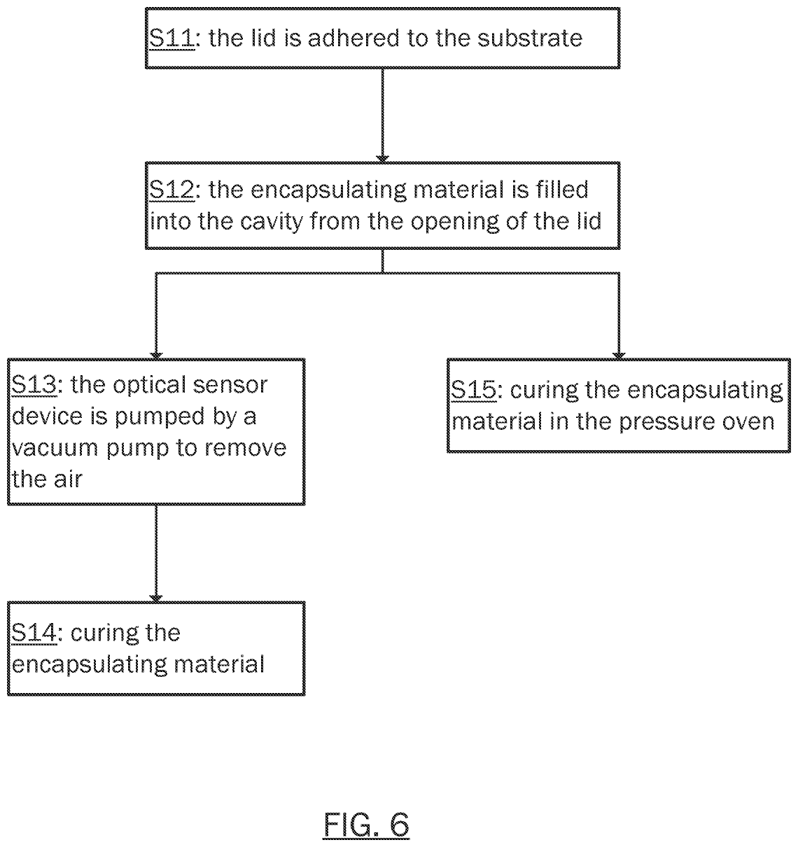

FIG. 6 shows an encapsulating process flow of an optical sensor device in accordance with one embodiment of the present disclosure. As shown in step S11, the lid is adhered to the substrate through an adhesion material. Then, as shown in step S12, the encapsulating material is filled into the cavity from the opening of the lid by ablation, printing, injection, dispensing, or the like. During the filling process, the encapsulating material may contain some gas (e.g., air bubbles). Subsequently, as shown in step S13, the optical sensor device is pumped by a vacuum pump to remove the gas in the encapsulating material. Next, as shown in step S13, the encapsulating material is cured to form an optical sensor device. In another embodiment, as shown in step S15, after the filling process, the encapsulating material can be cured in the pressure oven to remove the gas in the encapsulating material and cure the encapsulating material.

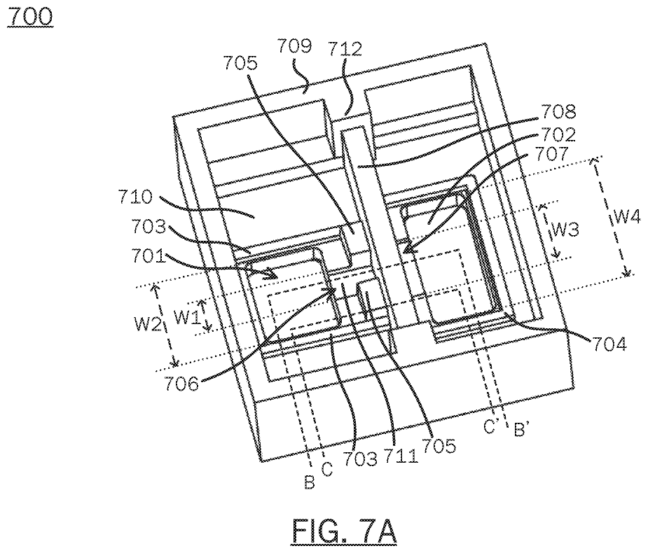

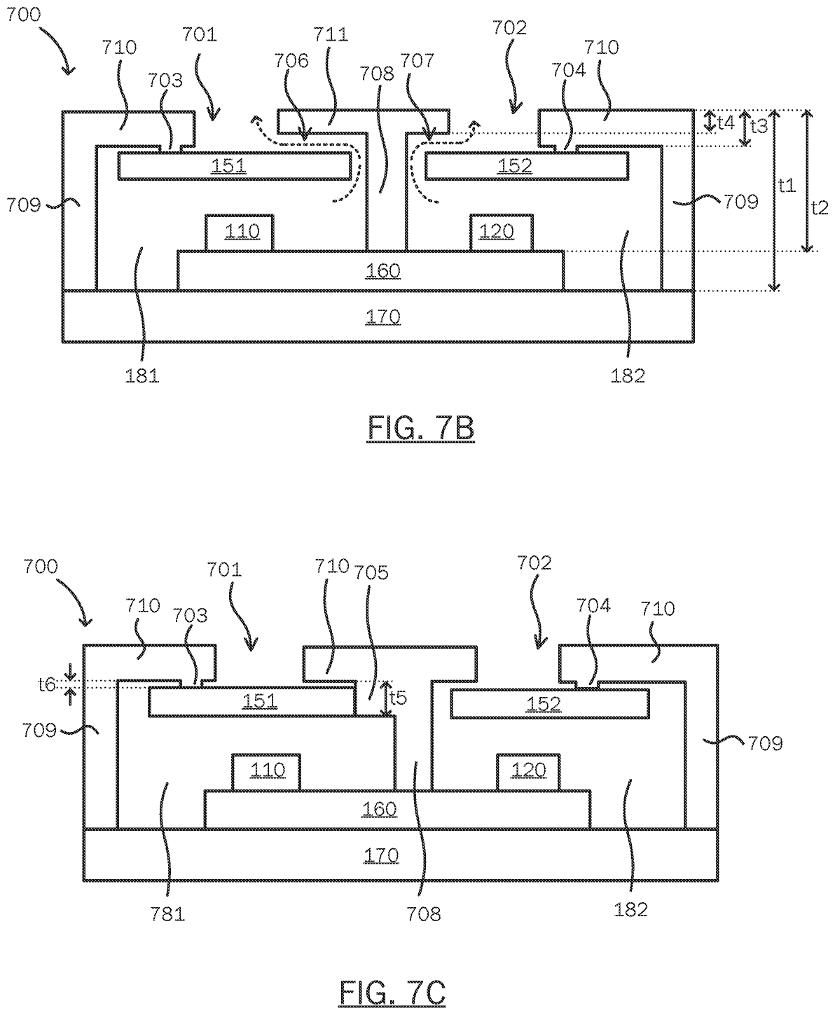

FIG. 7A shows a perspective view of a lid from the bottom side in accordance with one embodiments of the present disclosure. FIG. 7B shows a cross-sectional view taken along the line BB′ of the lid shown in FIG. 7A and assembled to form an optical sensor device. FIG. 7C shows a cross-sectional view taken along the line CC′ of the lid shown in FIG. 7A and assembled to form an optical sensor device. Referring to FIGS. 7A˜7C, the lid 700 in FIG. 7A is turned upside down and attached to the substrate 170 to protect the plurality of optoelectronic elements 110, 120, 130 (not shown in the figures), and the control element 160. The plurality of optoelectronic elements can include a light-receiving element 110 and a light-emitting element 120. The light-receiving element 110 and a light-emitting element 120 are disposed over and electrically connected to the control element 160 to form a stack structure which is placed on the substrate and enclosed by the lid 700. The lid 700 includes a dam 709, a first covering portion 710, a second covering portion 711, a partition wall 708, a first opening 701, and a second opening 702. The dam 709 is located in the peripheral region of the lid 700 and attached to the substrate 170 to enclose the plurality of optoelectronic elements 110, 120, and the control element 160. The first opening 701 located over the light-receiving element 110 for receiving the reflected light from the object (not shown), and the second opening 702 located over the light-emitting element 120 for transmitting the light emitted from the light-emitting element 120 towards the object (not shown). The partition wall 708 connected to the dam 709 and located between the light-receiving element 110 and the light-emitting element 120 to form a first cavity 181 for accommodating the light-receiving element 110 and a second cavity 182 for accommodating the light-emitting element 120. The light-receiving element 110 and the light-emitting element 120 are light isolated by the partition wall 708. The bottom end of the dam 709 is connected to the substrate 170, and the bottom end of the partition wall 708 is connected to the control element 160. The dam 709 has a thickness t1, and the partition wall 708 has a thickness t2 which is less than t1.

In an embodiment, the lid 700 also includes a connector 712 extending from the dam 709 and coupled with the partition wall 708. The connector 712 has the same thickness t1 as the dam 709 to connect to the substrate 170 for increasing the adhesion area between the lid 700 and the substrate 170.

The first covering portion 710 is connected to the dam 709 and surrounds the first opening 701 and the second opening 702 to cover the first cavity 181 and the second cavity 182 for blocking the unwanted light. A first transmissive plate 151 is adhered to the first covering portion 710 through an adhesive material (not shown) to cover the first opening 701. A second transmissive plate 152 is adhered to the first covering portion 710 through the adhesive material (not shown) to cover the second opening 702. The lid 700 further includes a first stopper 703 extending from the first covering portion 710 towards the first transmissive plate 151 and a second stopper 704 extending from the first covering portion 710 towards the second transmissive plate 152. The first stopper 703 is located at the peripheral area of the first opening 701 to prevent the adhesive material from flowing into the first opening 701 and affecting the light path of the light-receiving element 110. The second stopper 704 is located at the peripheral area of the second opening 702 to prevent the adhesive material from flowing into the second opening 702 and affecting the light path of the light-emitting element 120. The adhesive material (not shown) is disposed on the bottom side of the first covering portion 710 and between the first stopper 703 and the dam 709 to adhere to the first transmissive plate 151, and between the second stopper 704 and the dam 709 to adhere to the second transmissive plate 152.

The second covering portion 711 is connected to the first covering portion 710 and located between the first opening 701 and the second opening 702. The first covering portion 710 has a thickness t3, and the second covering portion 711 has a thickness t4 which is less than t3. The first transmissive plate 151 has a potion under the second covering portion 711 and the second transmissive plate 152 has a portion under the second covering portion 711. The first transmissive plate 151 is distant from the partition wall 708 by a non-zero distance and the second transmissive plate 152 is distant from the partition wall 708 by a non-zero distance. Since the thickness of the second covering portion 711 is thinner than that of the first covering portion 710, a first vent 706 is between the first transmissive plate 151 and the second covering portion 711 as a tunnel for air flow to stabilize the air pressure of the first cavity 181. Similarly, a second vent 707 between the second transmissive plate 152 and the second covering portion 711 is formed as a tunnel for air flow to stabilize the air pressure of the second cavity 182 to improve the reliability of the optical sensor device. The first vent 706 is coupled to the first opening 701 and the first cavity 181 and has a width W1 which is less than the width W2 of the first opening 701. The second vent 707 is coupled to the second opening 702 and the second cavity 182 and has a width W3 which is less than the width W4 of the second opening 702.

Referring to FIG. 7A and FIG. 7C, the area of the first opening 701 is less than that of the second opening 702, and the area of the first transmissive plate 151 may be less than that of the second transmissive plate 152. The first transmissive plate 151 may be easily misaligned when the adhesion process due to its smaller size. The lid 700 further includes two blockers 705 extending from the first covering portion 710 towards the substrate 170 for increasing the alignment accuracy of the first transmissive plate 151. The first transmissive plate 151 may by in contact with the two blockers 705 so that the first transmissive plate 151 can still maintain alignment during the adhesion process. The two blockers 705 are respectively located on two sides of the first vent 706 and coupled to the partition wall 708. The blocker 705 has a thickness t5 which is larger than the thickness t6 of the first stopper 703 or the second stopper 704.

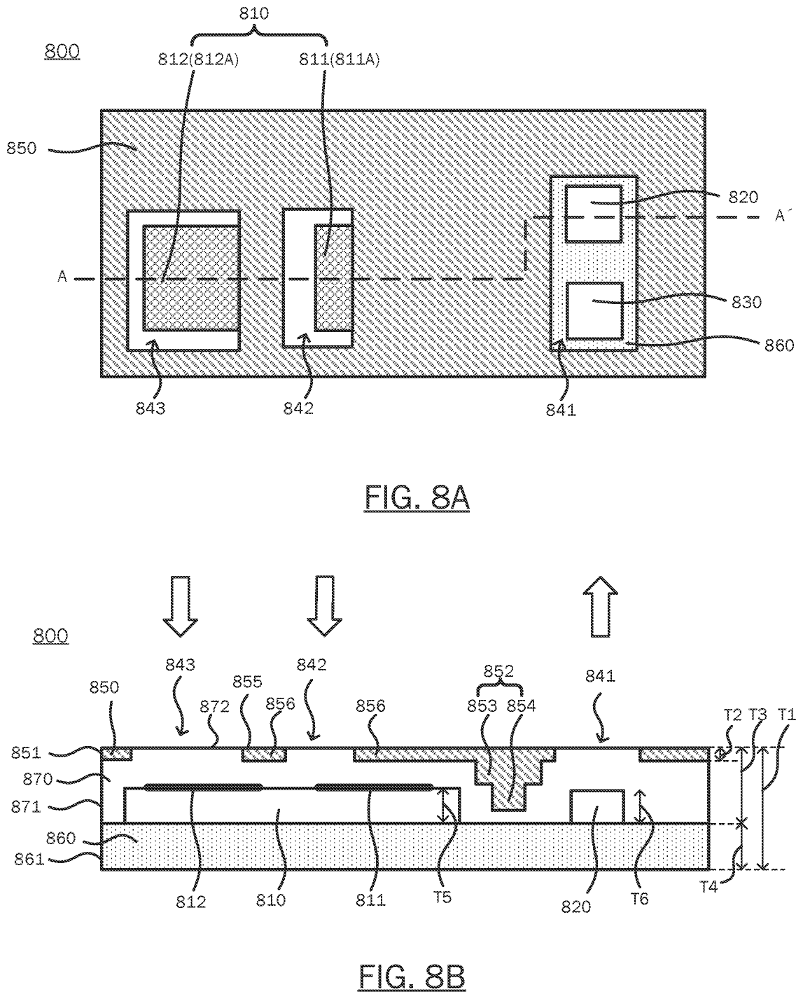

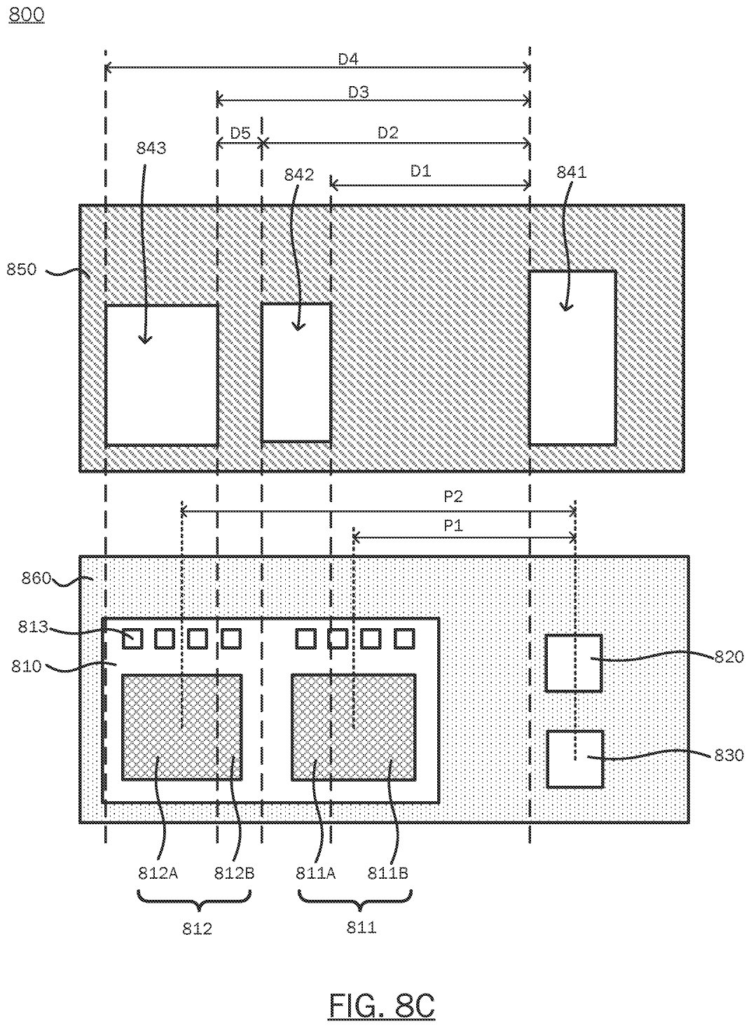

FIG. 8A shows a top view of an optical sensor device 800 in accordance with one embodiment of the present disclosure. FIG. 8B shows a cross-sectional view taken along the line AA′ in FIG. 8A. As shown in FIGS. 8A˜8B, the optical sensor device 800 includes a substrate 860, a light-receiving element 810, a plurality of light-emitting elements 820, 830, an encapsulating structure 870, and a shielding structure 850. The light-receiving element 810 and the plurality of light-emitting elements including but not limited to the first light-emitting element 820 and the second light-emitting element 830, are disposed on and electrically connected to the substrate 860. Unlike the optical sensor device described in reference to FIGS. 7A˜7C, the optical sensor device is encapsulated without a separate lid (e.g., lid 700).

In some embodiments, the encapsulating structure 870 is disposed over the substrate 860 to encapsulate the light-receiving element 810 and the plurality of light-emitting elements 820, 830. The encapsulating structure 870 can be a silicone-based resin or epoxy-based resin and transparent to the light transmitted from the light-emitting elements 820, 830, and the light detected by the light-receiving element 810. In one embodiment, the encapsulating structure 870 is transparent to a NIR light or a SWIR light. The encapsulating structure 870 directly contacts the top surface and the side surfaces of the light-receiving element 810, and directly contacts the top surfaces and the side surfaces of each light-emitting element 820, 830 for protecting the light-receiving element 810 and each light-emitting element 820, 830. The shielding structure 850 is disposed over and contacts the encapsulating structure 870 to block the unwanted light. The shielding structure 850 can be a silicone-based resin, or epoxy-based resin and contain a light-absorbing substance that blocks unwanted light.

The topmost surface 872 of the encapsulating structure 870 is coplanar with the topmost surface 855 of the shielding structure 850. In some embodiments, the respective side surfaces 851, 871, 861 of the shielding structure 850, the encapsulating structure 870, and the substrate 860 are coplanar. In an embodiment, a grinding process is performed on the encapsulating structure 870 to form the plurality of recesses for forming the shielding structure 850. In another embodiment, a removal process is performed on the encapsulating structure 870 for forming the plurality of recesses for forming the shielding structure 850.

The shielding structure 850 includes a covering portion 856 and a separation portion 852 to constrain the paths of the light emitted from the light-emitting elements 820, 830 and the light received by the light-receiving element 810. The covering portion 856 is located close to the top surface of the optical sensor device 800. The separation portion 852 extends from the covering portion 856 towards the substrate 860 and is located between the plurality of light-emitting elements 820, 830 and the light-receiving element 810 for enhancing the light isolation between the plurality of light-emitting elements 820, 830 and the light-receiving element 810. The separation portion 852 has a stepped shape which includes a narrower part 854 close to the substrate 860 and a wider part 853 close to the covering portion 856 and sandwiched between the covering portion 856 and the narrower part 854. The narrower part 854 is closer to the substrate 860 than the wider part 853. The separation portion 852 is distant from the substrate 860 by a distance of less than 50 μm. The encapsulating structure 870 is filled between the separation portion 852 and the substrate 860. In another embodiment, the separation portion 852 directly contacts the substrate 860.

The shielding structure 850 includes a first opening 841 for transmitting the light emitted from the plurality of light-emitting elements 820, 830 towards the object (not shown), and a plurality of openings, including but not limited to a second opening 842 and a third opening 843, for receiving the reflected light from the object (not shown). The second opening 842 and the third opening 843 are located over the light-receiving element 810. The first opening 841 is located over the plurality of light-emitting elements 820, 830. The light-receiving element 810 includes a plurality of separated absorption regions, including but not limited to a first absorption region 811 and a second absorption region 812, respectively facing the plurality of openings 842, 843 to increase the sensing optical power. One light-receiving element 810 corresponds to the plurality of openings 842, 843, and the plurality of light-emitting elements 820, 830 correspond to a single opening 141.

The first opening 841 is located over the light-emitting elements 820, 830. In the top view as shown in FIG. 8A, the area of the first opening 841 is larger than the overall area of the light-emitting elements 820, 830. The light-emitting elements 820, 830 are exposed under the first opening 841 of the shielding structure 850 in the top view. In the cross-sectional view as shown in FIG. 8B, the width of the first opening 841 is larger than the width of each light-emitting element 820, 830. Therefore, the light emitted from the light-emitting elements 820, 830 may be less blocked by the shielding structure 850. In another embodiment, the width of the first opening 841 is substantially equal to or slightly smaller than the width of each light-emitting element 820, 830.

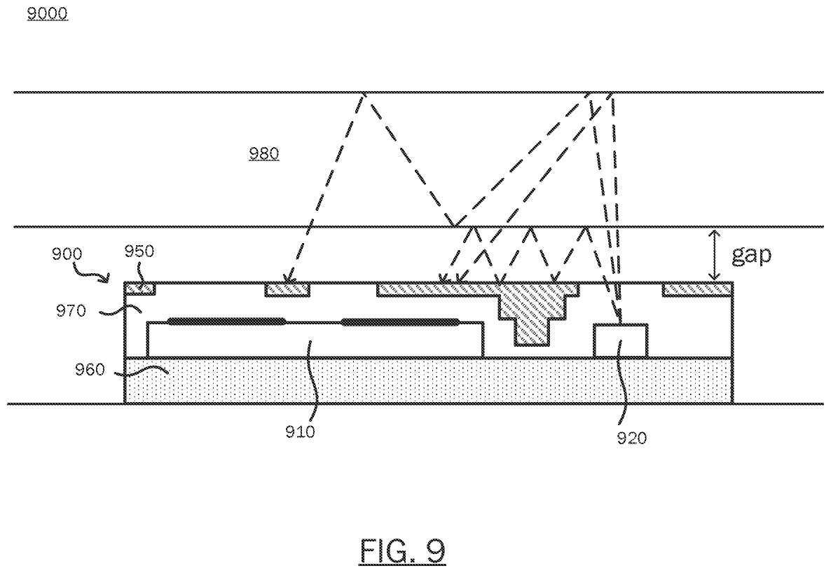

As shown in FIGS. 8A˜8B, the second opening 842 is located over the first absorption region 811 and the third opening 843 is located over the second absorption region 812. The dimension of the second opening 842 is different from that of the third opening 843. A distance between the first opening 841 and the third opening 843 is greater than a distance between the first opening 841 and the second opening 842, and an area of the third opening 843 is greater than that of the second opening 842. The distance between the first opening 841 above the light-emitting element and the second opening above the light-receiving element is closer, and the dimension of the opening above the light-receiving element is smaller. The area ratio of the third opening 843 to the second opening 842 is not less than 1.2 and in a range between 1.2 to 2. In this way, the crosstalk between the light-receiving element 810 and the light-emitting elements 820, 830 can be reduced. FIG. 9 shows a schematic diagram illustrating the crosstalk signal of a sensing module 9000 in accordance with one embodiment of the present disclosure. The sensing module 9000 includes an optical sensor device 900 and a cover 980 located over the optical sensor device 900 to form a package. The optical sensor device 900 can be one of aforementioned optical sensor device. The crosstalk signal received by the light-receiving element 910 may come from the interference light generated by the refraction and/or scattering of the light emitted from the light-emitting elements 920 through the encapsulating structure 970, the shielding structure 950, cover 980, and/or other external packaging structure.

FIG. 8C shows a schematic diagram illustrating the separation of the shielding structure 850 and the circuit of the optical sensor device 800. The circuit includes the light-receiving element 810 and the plurality of light-emitting elements 820, 830 disposed on the substrate 860. The light-receiving element 810 includes a plurality of electrode pads 813 disposed on the same side as the absorption regions 811, 812 of the light-receiving element 810. The plurality of electrode pads 813 are configured to be electrically connected to the substrate 860 through wires. As shown in FIGS. 8A˜8C, the first absorption region 811 includes a non-shielded portion 811A and a shielded portion 811B, and the second absorption region 812 includes a non-shielded portion 812A and a shielded portion 812B. In the top view, the non-shielded portion 811A and the non-shielded portion 812A are not shielded by and exposed to the shielding structure 850. The non-shielded portion 811A of the first absorption region 811 is exposed to an optical signal under the second opening 842, and the non-shielded portion 812A of the second absorption region 812 is exposed to the optical signal under the third opening 843. The shielded portion 811B of the first absorption region 811 and the shielded portion 812B of the second absorption region 812 are shielded from the optical signal by the shielding structure 850. In the cross-sectional view as shown in FIG. 8B, the shielded portion 811B of the first absorption region 811 and the shielded portion 812B of the second absorption region 812 are overlapped with the shielding structure 850 in a normal direction of the substrate 860. The distance between the first light-emitting element 820 and the absorption region is closer, and the dimension of the corresponding opening is smaller. As shown in FIG. 8C, the first light-emitting element 820 is closer to the first absorption region 811 than to the second absorption region 812, the area of the shielded portion 812B is smaller than that of the shielded portion 811B, and the area of the non-shielded portion 812A is larger than that of the non-shielded portion 811A. The area ratio of the non-shielded portion 812A to the shielded portion 112B of the second absorption region 812 is in a range between 4 to 6. The area ratio of the non-shielded portion 811A to the shielded portion 811B of the first absorption region 811 is in a range between 0.1 to 1. Notwithstanding some of the reflected light from the object is blocked by the shielding structure 850 and cannot be received by the non-shielded regions of the light-receiving element 810, the intensity of the received light is strong enough to calculate and determine a detecting signal, such as a PPG signal, proximity signal. In addition, the interference light due to crosstalk can also be effectively reduced.

As shown in FIG. 8C, in some embodiments the distance P1 between the first absorption region 811 and light-emitting element 820 (or 830) is not larger than 2 mm, preferably in a range between 0.8 to 1.5 mm. The distance P2 between the second absorption region 812 and light-emitting element 820 (or 830) is not larger than 3 mm, preferably in a range between 1.3 to 2.5 mm. The distance D1 between the leftmost side of the first opening 841 and the rightmost side of the second opening 842 is not less than 0.5 mm, preferably in a range between 0.5 to 1.2 mm. The distance D2 between the leftmost side of the first opening 841 and the leftmost side of the second opening 842 is in a range between 1 to 1.5 mm. The distance D3 between the leftmost side of the first opening 841 and the rightmost side of the third opening 843 is not less than 1.2 mm, preferably in a range between 1.2 to 1.8 mm. The distance D4 between the leftmost side of the first opening 841 and the leftmost side of the third opening 843 is in a range between 1.6 to 2.2 mm. The distance D5 between the second opening 842 and the third opening 843 is in a range between 0.1 to 0.5 mm. The ratio of the distance D3 to D1 is not less than 1.2, preferably in a range between 1.2 to 2.2. To make the optical sensor device small in size and have the advantage of low crosstalk, the sum of P1 and D1 is in a range between 1.5 to 2.5. The sum of P2 and D3 is in a range between 2.5 to 4. The crosstalk between the light-receiving element 810 and the light-emitting elements 820, 830 can be reduced by adjusting the distances D1, D2, D3, D4.

Referring back to FIG. 8B, in some embodiments the optical sensor device 800 has a thickness T1 that is not larger than 1 mm, preferably in the range between 0.3 to 1 mm. The covering portion 856 of the shielding structure 850 has a thickness T2 that is not greater than 0.3 mm, preferably in a range between 0.01 to 0.3 mm, to provide sufficient light-blocking property. The encapsulating structure 870 has a thickness T3 which is measured from the top surface of the substrate 860 to the topmost surface 872 of encapsulating structure 870. The thickness T3 is in a range between 0.2 to 0.5 mm to provide sufficient protecting property. The substrate 860 has a thickness T4 in a range between 0.1 to 0.4 mm. The light-receiving element 810 has a thickness T5 not more than 250 μm and in a range between 100 to 250 μm. Each light-emitting element 820, 830 has a thickness T6 not more than 250 μm and in a range between 100 to 250 μm. Correspondingly, the thickness of the optical sensor device 800 can be made quite thin, which is suitable for being installed in the wearable device with limited space.

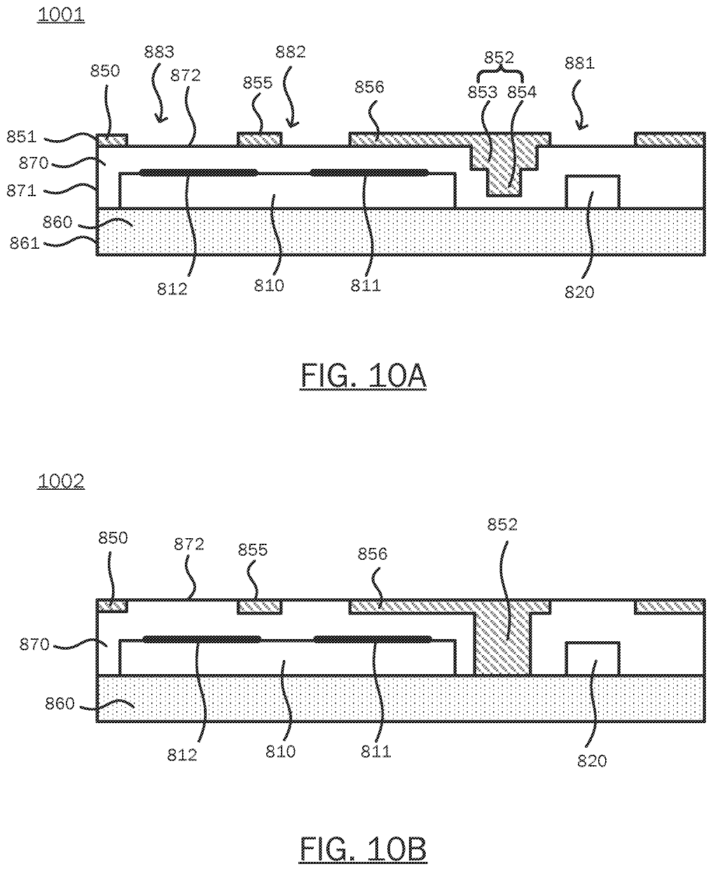

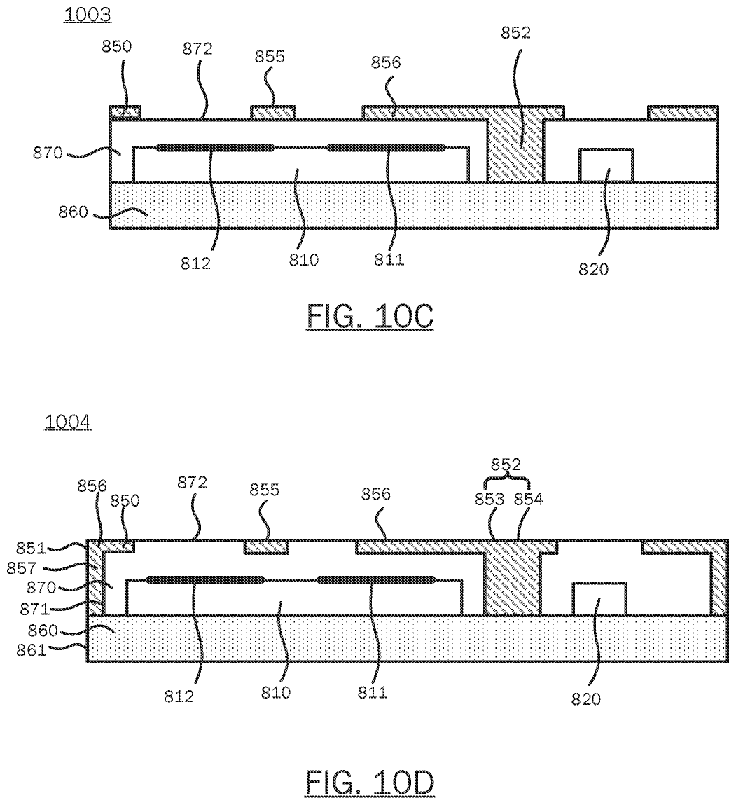

FIGS. 10A˜10F show the cross-sectional views of optical sensor devices in accordance with additional embodiments of the present disclosure. In another embodiment, the topmost surface 872 of the encapsulating structure 870 is not coplanar with the topmost surface 855 of the shielding structure 850. For example, as shown in the optical sensor device 1001 in FIG. 10A, the elevation of the topmost surface 872 of the encapsulating structure 870 is lower than that of the topmost surface 855 of the shielding structure 850. The covering portion 856 of the shielding structure 850 and the encapsulating structure 870 collectively form a plurality of recesses 881, 882, 883 on the top of the optical sensor device 1001. In an embodiment, a grinding process is performed on the encapsulating structure 870 before forming the shielding structure 850 on the encapsulating structure 870. The topmost surface 872 of the encapsulating structure 870 has a plurality of scratches. In another embodiment, a removal process is performed on the encapsulating structure 870 before forming the shielding structure 850 on the encapsulating structure 870.

In another embodiment, the separation portion 852 has a shape other than the stepped shape. For example, as shown in the optical sensor device 1002 in FIG. 10B, the separation portion 852 of the shielding structure 850 has a single-step (e.g., rectangular or sloped shape) and contacts the substrate 860 in the cross-sectional view. In some embodiments, the separation portion 852 is distant from the substrate 860 by a distance of less than 50 μm.

In another embodiment, as the optical sensor device 1003 shown in FIG. 10C, the separation portion 852 of the shielding structure 850 has a rectangular shape and contacts the substrate 860 in the cross-sectional view. The topmost surface 872 of the encapsulating structure 870 is not coplanar with the topmost surface 855 of the shielding structure 850. The elevation of the topmost surface 872 of the encapsulating structure 870 is lower than that of the topmost surface 855 of the shielding structure 850. In some embodiments, the separation portion 852 is distant from the substrate 860 by a distance of less than 50 μm.

In another embodiment, the shielding structure can surround the outer side surface of the encapsulating structure 870 to block the interference light that enters the optical sensor device. For example, as shown in the optical sensor device 1004 in FIG. 10D, the shielding structure 850 has a surrounding portion 857 extending from the covering portion 856 towards the substrate 860. The surrounding portion 857 surrounds the outer side surface 871 of the encapsulating structure 870 to prevent the emitting light from leaving the side of the optical sensor device 1004 and to prevent the interference light from entering the side of the optical sensor device 1004, thereby affecting the detection accuracy of the light-receiving element 810. The surrounding portion 857 directly contacts the outer side surface 871 of the encapsulating structure 870, and the size of the optical sensor device 1004 can be reduced.

When forming the separation portion 852 of the shielding structure 850, there may be an unexpected small gap between the separation portion 852 and upper surface 862 of the substrate 860 due to process variations. In another embodiment, as shown in the optical sensor device 1005 in FIG. 10E, a part of the separation portion 852 is embedded in the substrate 860. The elevation of the lower end 858 of the separation portion 852 can be lower than the upper surface 862 of the substrate 860 to ensure that there is no gap between the separation portion 852 and the upper surface 862 of the substrate 860 to achieve better light isolation between the light-receiving element 810 and the light-emitting elements 820, 830. This way, the crosstalk between the light-receiving element 810 and the light-emitting elements 820 and 830 can be reduced.

Improving the collimation of the light emitted by the light-emitting element may reduce the crosstalk between the light-emitting element and the light-receiving element. In another embodiment, as shown in the optical sensor device 1006 in FIG. 10F, a portion of the light-emitting element 820 is embedded into the substrate 860. The elevation of the bottom surface 821 of the light-emitting element 820 can be lower than the upper surface 862 of the substrate 860 so that the distance between the first opening 841 and the light-emitting element 820 is increased. This way, the light emitted by the light-emitting element 820 towards the object (not shown) is more collimated, further reducing the crosstalk between the light-emitting element 820 and the light-receiving element 810.

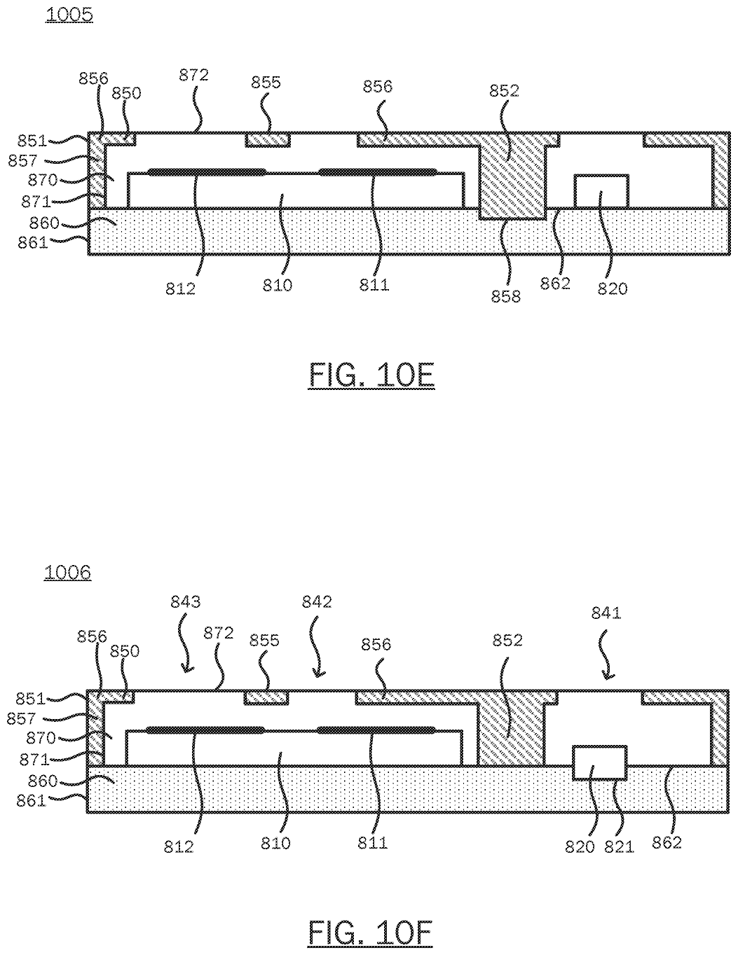

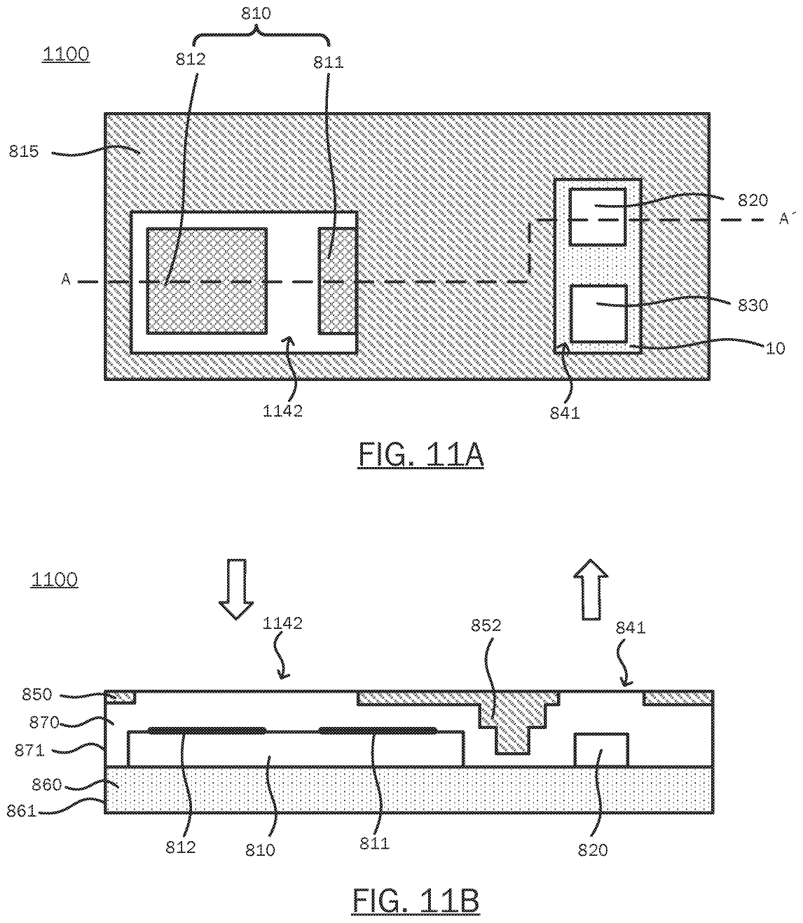

In another embodiment, the optical sensor device has one opening for receiving the reflected light from the object (not shown). FIG. 11A shows a top view of an optical sensor device 1100 in accordance with another embodiment of the present disclosure. FIG. 11B shows a cross-sectional view taken along the line AA′ in FIG. 11A. The optical sensor device 1100 has a similar structure to the optical sensor device 800. The shielding structure 850 includes a first opening 841 for transmitting the light emitted from the plurality of light-emitting elements 820, 830 towards the object (not shown), and a second opening 1142 for receiving the reflected light from the object (not shown). The second opening 1142 is located over the light-receiving element 810 which includes a plurality of separated absorption regions, including but not limited to a first absorption region 811 and a second absorption region 812. The plurality of separated absorption regions 811, 812 face the second opening 1142 to increase the sensing optical power. In the top view, the distance between the second absorption region 812 and the first light-emitting element 820 is farther than the distance between the first absorption region 811 and the light-emitting element 820. All area of the second absorption region 812 is exposed from the shielding structure 14, and a portion of the first absorption region 811 is shielded by the shielding structure 850.

FIG. 11C shows a schematic diagram illustrating the separation of the shielding structure 850 and the circuit of the optical sensor device 1100. As shown in FIGS. 11A˜11C, the first absorption region 811 includes a non-shielded portion 811A and a shielded portion 811B. In the top view, the second absorption region 812 and the non-shielded portion 811A of the first absorption region 811 are not shielded by and exposed from the shielding structure 850. The second absorption region 812 and the non-shielded portion 811A of the first absorption region 811 are exposed under the second opening 1142. The shielded portion 811B of the first absorption region 811 are shielded by the shielding structure 850. As shown in FIG. 11C, the area ratio of the non-shielded portion 811A to the shielded portion 811B of the first absorption region 811 is in a range between 0.4 to 1. Notwithstanding some of the reflected light from the object is blocked by the shielding structure 850 and cannot be received by the shielded region of the light-receiving element 810, the intensity of the received light is strong enough to calculate and determine a detecting signal, such as a PPG signal, proximity signal. In addition, the interference light due to crosstalk can also be effectively reduced. Since the second absorption region 812 is not shielded by the shielding structure 850, the intensity of the received light is stronger than the optical sensor device aforementioned. As shown in FIG. 11C, the distance D1 between the leftmost side of the first opening 841 and the rightmost side of the second opening 1142 is not less than 0.5 mm and in a range between 0.5 to 1.2 mm. The distance D4 between the leftmost side of the first opening 841 and the leftmost side of the second opening 1142 is in a range between 1.6 to 2.2 mm. The crosstalk between the light-receiving element 810 and the light-emitting elements 820, 830 can be reduced by adjusting the distances D1, D4.

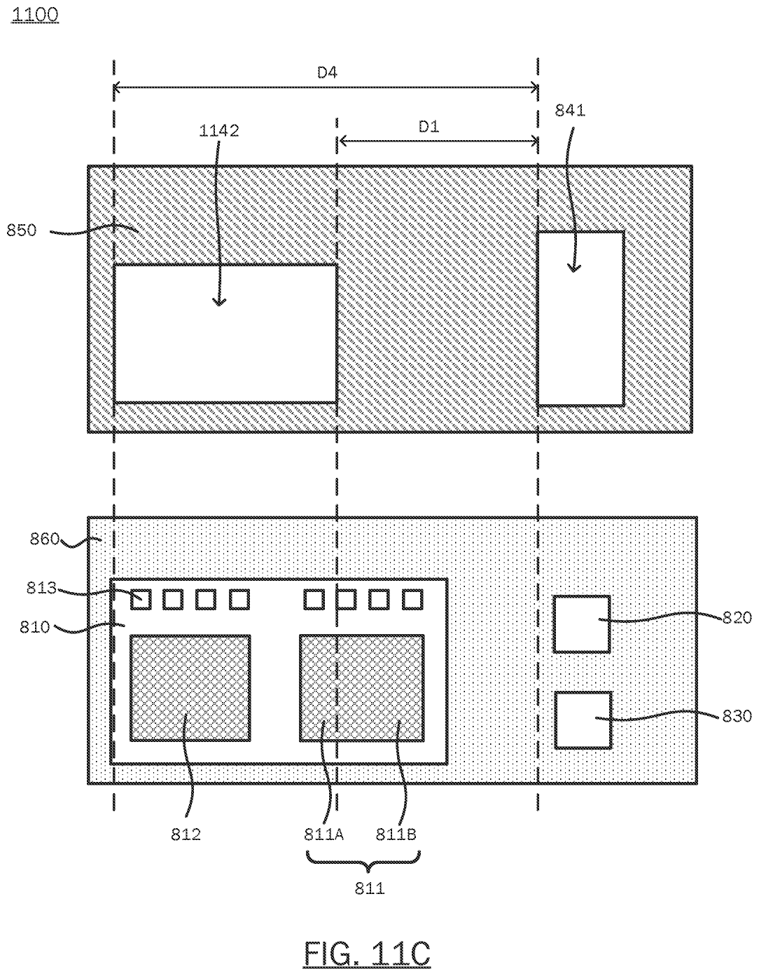

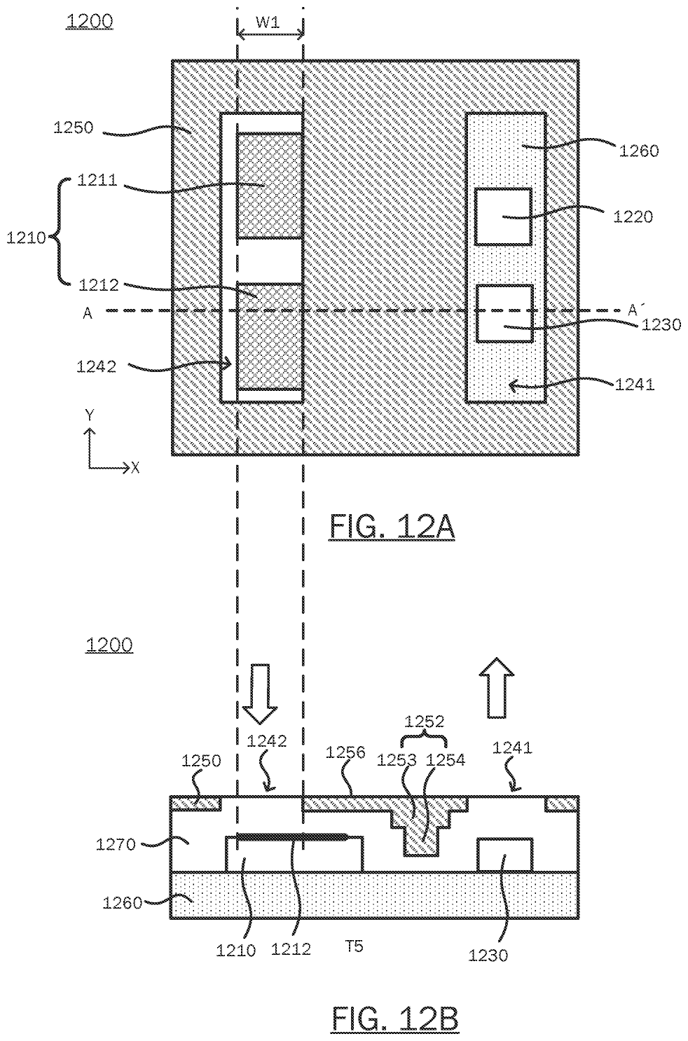

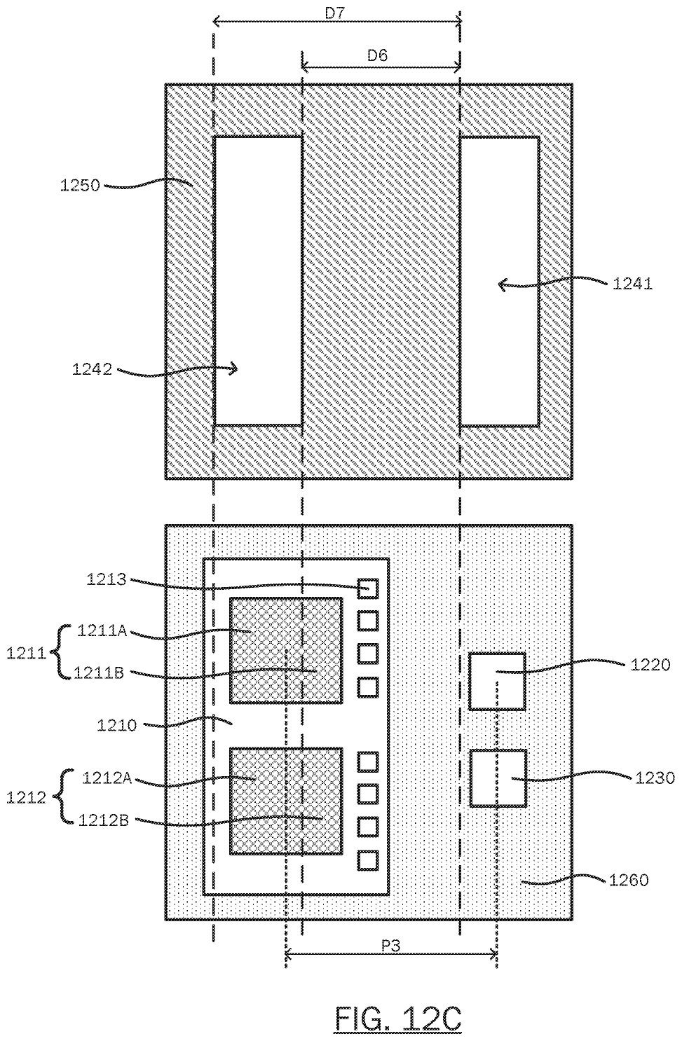

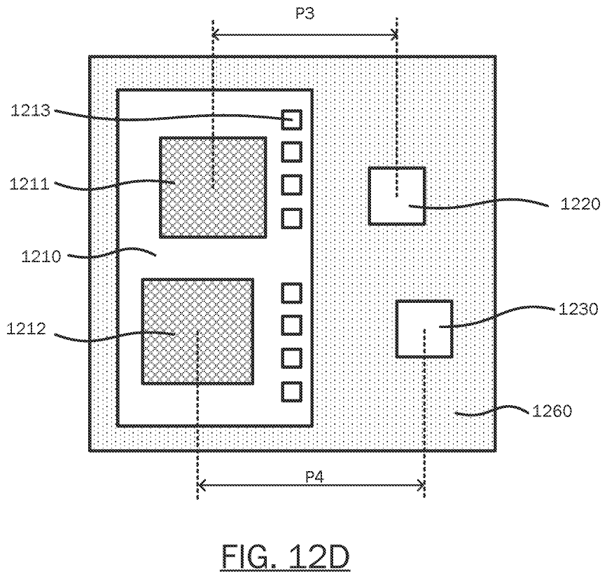

In the aforementioned embodiments, the arrangement direction of the plurality of absorption regions on the light-receiving element is different from the arrangement direction of the plurality of light-emitting elements. In another embodiment, the arrangement direction of the plurality of absorption regions on the light-receiving element can be the same as the arrangement direction of the plurality of light emitters, so that the size of the optical sensor device may be reduced. FIG. 12A shows a top view of an optical sensor device 1200 in accordance with one embodiment of the present disclosure. FIG. 12B shows a cross-sectional view taken along the line AA′ in FIG. 12A. As shown in FIGS. 12A˜12B, the optical sensor device 1200 includes a substrate 1260, a light-receiving element 1210, a plurality of light-emitting elements 1220, 1230, an encapsulating structure 1270, and a shielding structure 1250. The light-receiving element 1210 and the plurality of light-emitting elements 1220, 1230, including but not limited to the first light-emitting element 1220 and the second light-emitting element 1230, are disposed on and electrically connected to the substrate 1260. The plurality of light-emitting elements is arranged along the Y direction. The light-receiving element 1210 includes a plurality of separated absorption regions, including but not limited to a first absorption region 1211 and a second absorption region 1212, arranged along the Y direction which is the same as the arrangement direction of the plurality of light-emitting elements.

The encapsulating structure 1270 is disposed over the substrate 1260 to encapsulate the light-receiving element 1210 and the plurality of light-emitting elements 1220, 1230. The shielding structure 1250 is disposed over and contacts the encapsulating structure 1270 to block the unwanted light. The shielding structure 1250 includes a covering portion 1256 and a separation portion 1252 to constrain the paths of the light emitted from the light-emitting elements 1220, 1230 and the light received by the light-receiving element 1210. The covering portion 1256 is located close to the top surface of the optical sensor device 1200. The separation portion 1252 extends from the covering portion 1256 towards the substrate 1260 and is located between the plurality of light-emitting elements 1220, 1230 and the light-receiving element 1210 for enhancing the light isolation between the plurality of light-emitting elements 1220, 1230 and the light-receiving element 1210. The separation portion 1252 is similar to the separation portion 852 in FIG. 8B and has a stepped shape which includes a narrower part 1254 close to the substrate 1260 and a wider part 1253 close to the covering portion 1256 and sandwiched between the covering portion 1256 and the narrower part 1254. The structure of the separation portion is similar to that in FIG. 8B, and can refer to the aforementioned descriptions.

The shielding structure 1250 includes a first opening 1241 for transmitting the light emitted from the plurality of light-emitting elements 1220, 1230 towards the object (not shown) and a second opening 1242 for receiving the reflected light from the object (not shown). The first opening 1241 is located over the light-emitting elements 1220, 1230. The area of the first opening 1241 is larger than the overall area of the light-emitting elements 1220, 1230. The light-emitting elements 1220, 1230 are exposed under the first opening 1241 of the shielding structure 1250. The second opening 1242 is located over the light-receiving element 1210. The first opening 1241 is located over the plurality of light-emitting elements 1220, 1230. The first absorption region 1211 and the second absorption region 1212 of the light-receiving element 1210 face the second opening 1242.

FIG. 12C shows a schematic diagram illustrating the separation of the shielding structure 1250 and the circuit of the optical sensor device 1200. The circuit includes the light-receiving element 1210 and the plurality of light-emitting elements 1220, 1230 disposed on the substrate 1260. The light-receiving element 1210 includes a plurality of electrode pads 1213 disposed on the same side as the absorption regions 1211, 1212 of the light-receiving element 1210. The plurality of electrode pads 1213 are configured to be electrically connected to the substrate 1260 through wires. As shown in FIGS. 12A˜12C, the first absorption region 1211 includes a non-shielded portion 1211A and a shielded portion 1211B, and the second absorption region 1212 includes a non-shielded portion 1212A and a shielded portion 1212B. In the top view, the non-shielded portion 1211A and the non-shielded portion 1212A are not shielded by and exposed to the shielding structure 1250. The non-shielded portion 1211A of the first absorption region 1211 and the non-shielded portion 1212A of the second absorption region 1212 is exposed to the optical signal under the second opening 1242. The shielded portion 1211B of the first absorption region 1211 and the shielded portion 1212B of the second absorption region 1212 are shielded from the optical signal by the shielding structure 1250. The width W1 of the non-shielded portion 1211A is the same as the width of the non-shielded portion 1212A.

Since the distance between the light-emitting element 1230 (or 1220) and the light-receiving element 1210 is close, a portion of the absorption area near to the light-emitting element needs to be shielded to reduce crosstalk. The area ratio of the non-shielded portion to the shielded portion of the first absorption region 1211 is the same as the area ratio of the non-shielding part to the shielding part of the second base absorption region 1212, which is in a range of 0.3˜3. Notwithstanding some of the reflected light from the object is blocked by the shielding structure 1250 and cannot be received by the non-shielded regions of the light-receiving element 810, the intensity of the received light is strong enough to calculate and determine a detecting signal, such as a PPG signal, proximity signal. In addition, the interference light due to crosstalk can also be effectively reduced. The distance P3 between the light-receiving element 810 and light-emitting element 1230 (or 1220) is not larger than 1.5 mm, preferably in a range between 0.8 to 1.4 mm. The distance D6 between the leftmost side of the first opening 1241 and the rightmost side of the second opening 1242 is not less than 0.5 mm, preferably in a range between 0.7 to 2 mm. The distance D7 between the leftmost side of the first opening 1241 and the leftmost side of the second opening 1242 is not less than 1 mm, preferably in a range between 1.2 to 1.5 mm. To make the optical sensor device small in size and have the advantage of low crosstalk, the sum of P3 and D6 is in a range between 1.5 to 3. The crosstalk between the light-receiving element 1210 and the light-emitting elements 1220, 1230 can be reduced by adjusting the distances D6 and D7.

In another implementation, the distance between each absorption region and the light-emitting element may be different depending on the operation wavelength or application. For example, as shown in FIG. 12D, the distance between the first absorption region 1211 and the first light-emitting element 1220 is P3, the distance between the second absorption region 1212 and the second light-emitting element 1230 is P4, and P4 is different from P3.

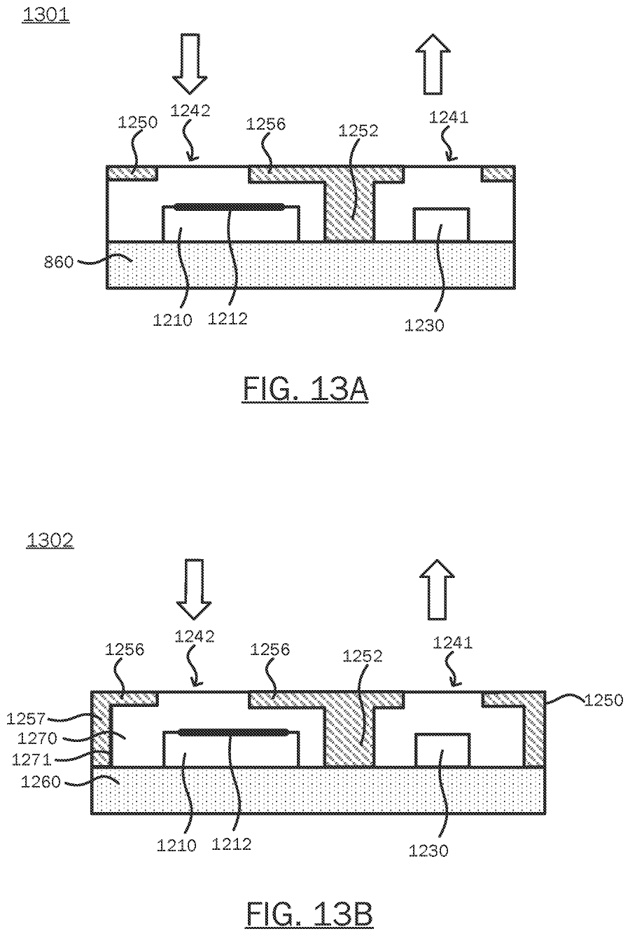

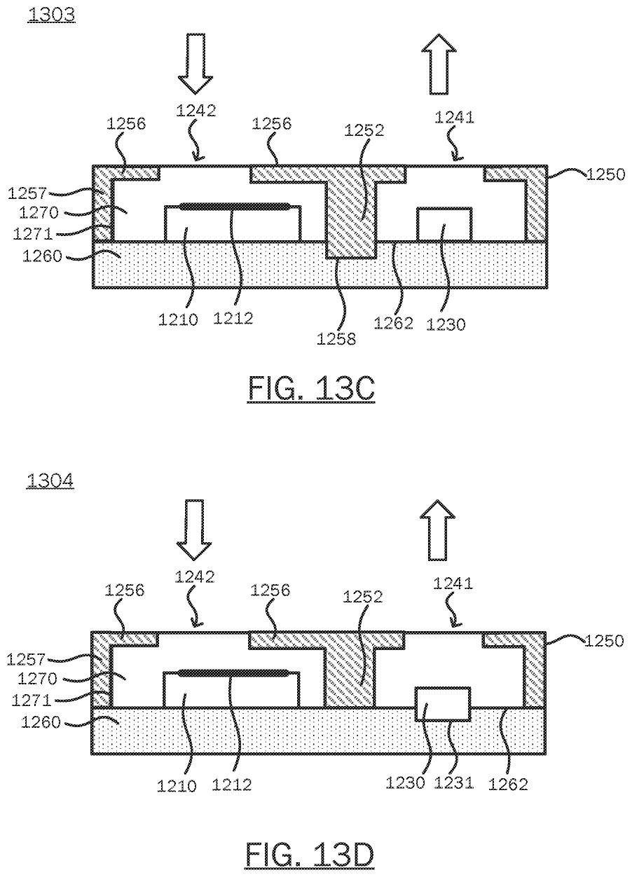

FIGS. 13A˜13D show the cross-sectional views of other optical sensor devices in accordance with different embodiments of the present disclosure. In other embodiment, the separation portion 1252 of the shielding structure 1250 can be other shape, such as a rectangular shape. For example, as shown in the optical sensor device 1301 in FIG. 13A, the separation portion 1252 of the shielding structure 1250 has a rectangular shape and contacts the substrate 1260 in the cross-sectional view. In another embodiment, the separation portion 1252 is distant from the substrate 1260 by a distance of less than 50 μm. In another embodiment, the shielding structure 1250 can surround the outer side surface of the encapsulating structure 1270 to block the interference light that enters the optical sensor device. For example, as shown in the optical sensor device 1302 in FIG. 13B, the shielding structure 1250 has a surrounding portion 1257 extending from the covering portion 1256 towards the substrate 1260. The surrounding portion 1257 surrounds the outer side surface 1271 of the encapsulating structure 1270 to prevent the emitting light from leaving the side of the optical sensor device 1302 and to prevent the interference light from entering the side of the optical sensor device 1304, thereby affecting the detection accuracy of the light-receiving element 1210. The surrounding portion 1257 directly contacts the side surface 1271 of the encapsulating structure 1270, and the size of the optical sensor device 1302 can be reduced.

When forming the separation portion 1252 of the shielding structure 1250, there may be an unexpected small gap between the separation portion 1252 and upper surface 1262 of the substrate 1260 due to process variations. For example, as shown in the optical sensor device 1303 in FIG. 13C, a portion of the separation portion 1252 is embedded in the substrate 1260. The elevation of the lower end 1258 of the separation portion 1252 can be lower than the upper surface 1262 of the substrate 1260 to ensure that there is no gap between the separation portion 1252 and the upper surface 1262 of the substrate 1260 to achieve better light isolation between the light-receiving element 1210 and the light-emitting elements 1230. This way, the crosstalk between the light-receiving element 1210 and the light-emitting elements 1220 and 1230 can be reduced.

Improving the collimation of the light emitted by the light-emitting element may reduce the crosstalk between the light-emitting element and the light-receiving element. In another embodiment, as shown in the optical sensor device 1304 in FIG. 13D, a portion of the light-emitting element 1230 is embedded into the substrate 1260. The elevation of the bottom surface 1231 of the light-emitting element 1230 can be lower than the upper surface 1262 of the substrate 1260 so that the distance between the first opening 1241 and the light-emitting element 1230 is increased. This way, the light emitted by the light-emitting element 1230 towards the object (not shown) is more collimated, further reducing the crosstalk between the light-emitting element 1230 and the light-receiving element 1210.

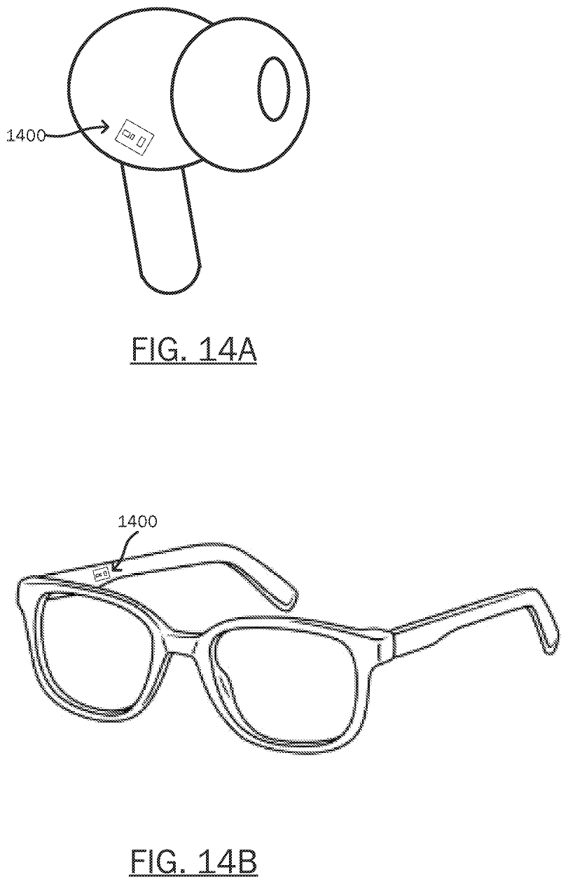

FIGS. 14A˜14B show different wearable devices including the optical sensor device in accordance with different embodiments of the present disclosure. FIG. 14A shows an earbud including an optical sensor device 1400. When the user wears the earbud to listen to music or communicate, the optical sensor device 1400 contacts the skin of the user and can be configured to measure various bioinformation at the same time. FIG. 14B shows a pair of glasses including an optical sensor device 1400. When the user wears a pair of glasses, the optical sensor device 1400 contacts the skin of the user and can be configured to measure various bioinformation at the same time. The optical sensor device 1400 can be one of the aforementioned optical sensor devices. FIGS. 14A˜14B show two examples of wearable devices, however suitable wearable devices such as helmet, wristband, watch, can be installed the optical sensor device to measure various bioinformation.

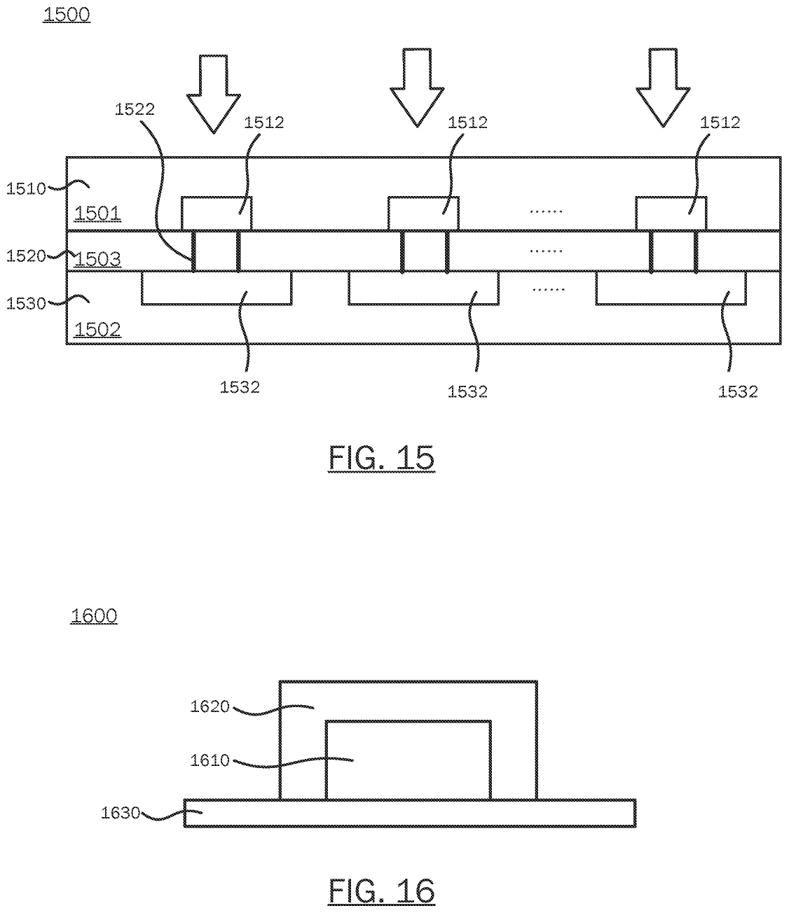

FIG. 15 shows a light-receiving element in accordance with one embodiment of the present disclosure. The light-receiving element 1500 includes a photoelectronic devices 1501, a control device 1502, and a bonding interface 1503. The photoelectronic devices 1501 and the control device 1502 are wafer-bonded via a bonding interface 1503 (e.g., oxide or any other suitable materials). The photoelectronic devices 1501 includes a first substrate 1510 and a plurality of detecting regions 1512 deposited on the first substrate 1510. The control device 1502 includes a second substrate 1530 and a plurality of corresponding circuitry areas 1532 carried by the second substrate 1530. Each circuitry area 1532 is electrically coupled to the corresponding detecting region 1512 through the conductive route 1522 of the bonding interface 1503. The first substrate 1510 and the second substrate 1530 can both be a silicon substrate. The detecting region 1512 includes a material can be different from (e.g., fabricated from a heterogeneous material) or the same as (e.g., fabricated from a homogeneous material) the first substrate 1510. In one embodiment, the material of the detecting region 1512 that can include III-V material, such as P, N, Ga, In, Al. In another embodiment, the material of the detecting region 1512 can include IV material such as germanium (Ge), Si.

FIG. 16 shows an optical sensor module in accordance with one embodiments of the present disclosure. The optical sensor module includes a carrier board 1630, an optical sensor device 1610, and a sealing structure 1620. The optical sensor device 1610 can be any one of the aforementioned optical sensor devices and is disposed on the carrier board 1630. The sealing structure 1620 is disposed over the carrier board 1630 to seal the optical sensor device 1610. The sealing structure 1620 may directly contact the top surface and the side surfaces of the optical sensor device 1610 for protecting the optical sensor device 1610. In one embodiment, the sealing structure 1620 may include an optical structure, which is configured to adjust the light emission direction of the light-emitting element and also increase or collimate the light-receiving angle of the light-receiving element.

While the disclosure has been described by way of example and in terms of a preferred embodiment, it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An optical sensor device, comprising:
a substrate;
a light-receiving element comprising a first absorption region, and disposed on and electrically connected to the substrate;
a first light-emitting element disposed on and electrically connected to the substrate;
an encapsulating structure disposed over the substrate, and encapsulating the first light-emitting element and the light-receiving element; and
a shielding structure disposed over the encapsulating structure, comprising a first opening located over the first light-emitting element, and a second opening located over the light-receiving element,
wherein the first absorption region comprises a non-shielded portion exposed to an optical signal under the second opening of the shielding structure and a shielded portion shielded from the optical signal by the shielding structure.

2. The optical sensor device of claim 1, wherein the shielding structure directly contacts the encapsulating structure.

3. The optical sensor device of claim 1, further comprising a second light-emitting element disposed on and electrically connected to the substrate, wherein the first light-emitting element and the second light-emitting element are exposed under the first opening of the shielding structure.

4. The optical sensor device of claim 1, wherein the shielding structure comprises a third opening separated from the second opening and located over the light-receiving element.

5. The optical sensor device of claim 4, wherein a dimension of the second opening is different from that of the third opening.

6. The optical sensor device of claim 4, wherein a distance between the first opening and the third opening is larger than a distance between the first opening and the second opening, and wherein an area of the third opening is larger than that of the second opening.

7. The optical sensor device of claim 4, wherein an area ratio of the third opening to the second opening is in a range between 1.2 to 2.

8. The optical sensor device of claim 4, wherein the light-receiving element comprises a second absorption region separated from the first absorption region, the second absorption region comprises a shielded portion shielded by the shielding structure and a non-shielded portion is exposed under the third opening.

9. The optical sensor device of claim 8, wherein the first light-emitting element is closer to the first absorption region than to the second absorption region, and wherein an area of the shielded portion of the second absorption region is smaller than that of the shielded portion of the first absorption region.

10. The optical sensor device of claim 8, wherein a distance between the first light-emitting element and the second absorption region is greater than a distance between the first light-emitting element and the first absorption region, and wherein an area of the non-shielded portion of the second absorption region is greater than that of the non-shielded portion of the first absorption region.

11. The optical sensor device of claim 1, wherein the shielding structure comprises a covering portion and a separation portion extending from the covering portion toward the substrate.

12. The optical sensor device of claim 11, wherein the separation portion is located between the first light-emitting element and the light-receiving element.

13. The optical sensor device of claim 11, wherein the separation portion is distant from the substrate and the encapsulating structure is filled between the separation portion and the substrate.

14. The optical sensor device of claim 11, wherein the separation portion has a stepped shape which includes a narrower part and a wider part, and wherein the narrower part is closer to the substrate than the wider part.

15. The optical sensor device of claim 1, wherein a topmost surface of the encapsulating structure is coplanar with that of the shielding structure.

16. The optical sensor device of claim 1, wherein a topmost surface of the encapsulating structure has an elevation lower than that of the shielding structure.

17. The optical sensor device of claim 1, wherein the light-receiving element comprises a second absorption region separated from the first absorption region and is exposed from the shielding structure.

18. The optical sensor device of claim 1, wherein a topmost surface of the encapsulating structure has a plurality of scratches.

19. The optical sensor device of claim 1, wherein the encapsulating structure comprises a material transparent to a NIR light or a SWIR light.

20. The optical sensor device of claim 1, wherein the light-receiving element comprises a photoelectronic device having a detecting region comprising germanium.
